(19) United States
(12) Patent Application Publication
(10) Pub. No.: US 2024/0008199 A1
(43) Pub. Date: Jan. 4, 2024

(54) Communication Cart and Communication Case

(71) Applicant: Kevin Patel, Garland, TX (US)

(72) Inventor: Kevin Patel, Garland, TX (US)

(21) Appl. No.: 18/344,822

(22) Filed: Jun. 29, 2023

Related U.S. Application Data
(60) Provisional application No. 63/357,062, filed on Jun. 30, 2022.

(51) Int. Cl. H05K 5/02

(52) U.S. Cl. CPC H05K 5/0217

(57) ABSTRACT

Disclosed are a communication case and a communication cart. A communication case may include at least: a case with a sealed compartment; a battery within the sealed compartment; a modem within the sealed compartment and powered by the battery; and a WIFI transceiver within the sealed compartment and powered by the battery. The modem and WIFI transceiver may connect external user devices to endpoints over available wireless communication channels. A communication cart may include: a communication compartment with at least a modem and a WIFI transceiver to connect external user devices to endpoints over available wireless communication channels; a sanitization station, wherein the sanitization station includes a sanitization system configured to sanitize a user device; and a set of wheels for maneuvering the communication cart.

### CROSS-REFERENCE TO RELATED APPLICATION(S)

This application claims the benefit of priority under 35 U.S.C. § 119 from U.S. Provisional Patent Application No. 63/357,062, filed on Jun. 30, 2022, entitled “Communication Cart and Communication Case,” the contents of which is incorporated by reference in its entirety.

### TECHNICAL FIELD

Various aspects of the present disclosure relate generally to communication cases and communication carts and, more particularly, to methods of making and using communication cases and communication carts.

### BACKGROUND

Generally, aging infrastructure is difficult to support with fixed connectivity solutions. Moreover, certain environments, such as healthcare organizations, military organizations, and mobile organizations (e.g., rescue or humanitarian missions and the like), require connectivity without being necessarily near fixed electricity sources. Furthermore, in the case of healthcare (and generally), sanitization is a high priority due to infectious diseases, such as COVID-19 and the like.

The present disclosure is directed to overcoming one or more of these above-referenced challenges.

### SUMMARY OF THE DISCLOSURE

According to certain aspects of the disclosure, systems, methods, and computer readable memory are disclosed for communication cases and communication carts.

For instance, a communication case may include at least: a case with a sealed compartment; a modem within the sealed compartment; and a WIFI transceiver within the sealed compartment. The modem and WIFI transceiver may connect external user devices to endpoints over available wireless communication channels.

In addition, a communication cart may include: a communication compartment with at least a modem and a WIFI transceiver to connect external user devices to endpoints over available wireless communication channels; a sanitization station, wherein the sanitization station includes a sanitization system configured to sanitize a user device; and a set of wheels for maneuvering the communication cart.

In addition, a communication case adopted for exposure to biological material may include: a case, wherein the case includes two compartments within an interior volume of the case, wherein the case is configured to be opened to provide access to a first compartment of the two compartments; a panel, wherein the panel is positioned to separate a sealed compartment of the two compartments within the case from the first compartment, and wherein the panel seals the sealed compartment from an exterior of the case and from the first compartment; a modem position within the sealed compartment; a WIFI transceiver positioned within the sealed compartment; and a power switch disposed on the exterior of the case, wherein the power switch is coupled to the modem, such that a user may operate the power switch to initiate a first wireless communication channel between the modem and a cellular node and a second communication channel between the WIFI transceiver and a user device, external to the sealed compartment, without accessing an interior of the sealed compartment and without disrupting the seal, thereby enabling relay of data packets between an endpoint and the user device.

In addition, a communication cart may include: a communication compartment, wherein the communication compartment includes: a modem positioned within the communication compartment, and a WIFI transceiver positioned within the communication compartment, wherein the modem is configured to initiate a first wireless communication channel between the modem and a cellular node and a second communication channel between the WIFI transceiver and a user device, thereby enabling relay of data packets between an endpoint and the user device; a sanitization station, wherein the sanitization station includes a sanitization system configured to sanitize the user device; and a set of wheels for maneuvering the communication cart.

Additional objects and advantages of the disclosed technology will be set forth in part in the description that follows, and in part will be apparent from the description, or may be learned by practice of the disclosed technology.

It is to be understood that both the foregoing general description and the following detailed description are exemplary and explanatory only and are not restrictive of the disclosed technology, as claimed.

### BRIEF DESCRIPTION OF THE DRAWINGS

The accompanying drawings, which are incorporated in and constitute a part of this specification, illustrate various exemplary aspects and together with the description, serve to explain the principles of the disclosed technology.

FIG. 1 depicts an example environment for communication cases and communication carts.

FIGS. 2A and 2B depict block diagrams schematically showing a communication case and a communication cart.

FIGS. 3A and 3B depict block diagrams schematically showing a communication case or a communication case selecting a wireless communication channel and relaying data packets between a user device and an endpoint, via a selected wireless communication channel.

FIGS. 4A-4I depict features, and a method of manufacturing, a communication case.

FIGS. 5A-5H depict features, and a method of manufacturing, a communication cart.

FIG. 6 depicts a flowchart of an exemplary routine for selecting a wireless communication channel and relaying data packets using the selected wireless communication channel.

FIG. 7 depicts a flowchart of an exemplary routine for injecting a remote SIM into a modem of a communication cart or a communication case.

FIG. 8 depicts a flowchart of an exemplary routine for serving edge node processes.

FIG. 9 depicts an example system that may execute techniques presented herein.

### DETAILED DESCRIPTION

In general, the present disclosure is directed to communication cases and communication carts. As discussed in detail herein, communication cases and communication carts systems of the present disclosure may provide data connectivity to use devices to endpoints while also providing a reduction in exposure to infectious diseases and/or biological materials.

In some cases, a communication case may include at least: a case with a sealed compartment; a modem within the sealed compartment; and a WIFI transceiver within the sealed compartment. The modem and WIFI transceiver may connect external user devices to endpoints over available wireless communication channels. Thus, the user device may have data connectivity without having access to the communication equipment directly and the communication case may be easily cleaned by a user. In some cases, the communication case may also include a charging port disposed on the exterior of the case that provides a charging connection on an interior wall of the case in the sealed compartment; and a battery positioned within the sealed compartment and configured to be charged by the charging connection when an external charging device is connected to the charging port.

In some cases, a communication cart may include: a communication compartment with at least a modem and a WIFI transceiver to connect external user devices to endpoints over available wireless communication channels; a sanitization station, wherein the sanitization station includes a sanitization system configured to sanitize a user device; and a set of wheels for maneuvering the communication cart. Thus, the user device may have data connectivity without having access to the communication equipment directly and the communication cart may sanitize the user device, thereby increasing safety or reducing transmission of diseases.

Thus, methods and systems of the present disclosure may be improvements to computer technology (e.g., mobile communication systems) and/or sanitization system.

Environment

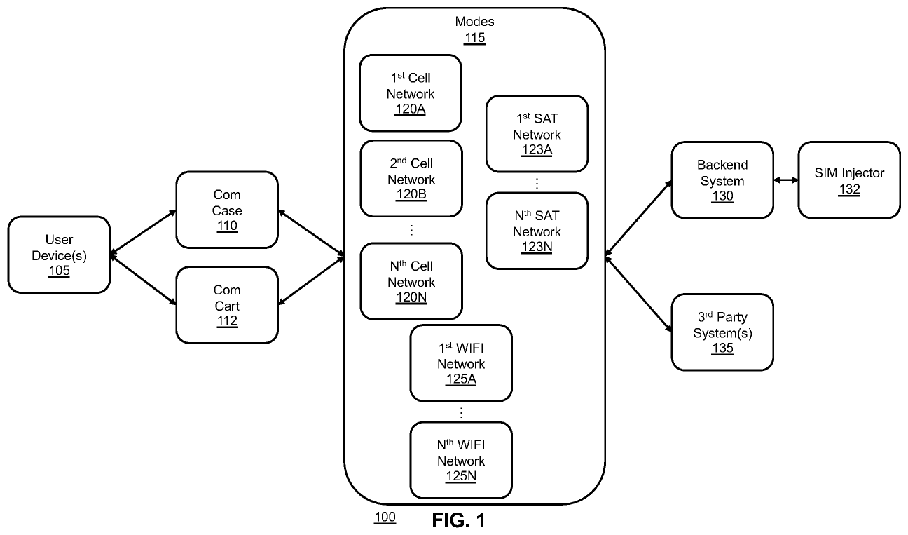

FIG. 1 depicts an example environment 100 for communication cases 110 and communication carts 112. The environment 100 may include user device(s) 105, a communication case 110, a communication cart 112, modes 115, a backend system 130, and third-party system(s) 135. Generally, as discussed herein, the user device(s) 105 may connect to the third-party system(s) 135 or the backend system 130, via the communication case 110 or the communication cart 112 over available modes of the modes 115.

The user device(s) 105 (hereinafter referred to as “user device 105” for clarity of reference) may be various different types of devices, including medical devices, computing devices, personal devices, extended reality (XR) devices, and the like, that communicate using wired (e.g., ethernet, and the like) or wireless communication standards (e.g., WIFI, and the like). In some cases, the user device 105 may be a medical device operated by a user (e.g., a healthcare worker, patient, etc.), such as a patient monitoring system, a medical data entry system, and the like. In some cases, the user device 105 may be a connected medical device operated by a user (e.g., a healthcare worker), such as a telehealth system, a drug delivery system, an operating device, and the like. In some cases, the user device 105 may be a computing device operated by a user to enter data and/or interact with remote servers/applications, such as a maintenance system or IT system. In some cases, the user device 105 may be a computing device operated by a user to conduct audio/visual presentation or interaction, such as presentation systems, audio/video conferencing systems, and/or learning systems. In some cases, the user device 105 may be a personal device operated by a user to enter data and/or interact with remote servers/applications, such as a mobile phone, a laptop computer, a desktop computer, tablet, a smart watch, and the like. In some cases, the user device 105 may be an XR device operated by a user to interact with XR applications, such as virtual reality devices, augmented reality devices, mixed reality devices, and the like. Generally, one or more such user devices 105 may connect to the communication case 110 or the communication cart 112, via a WIFI network broadcast by the communication case 110 or the communication cart 112 and/or ethernet ports on the communication case 110 or the communication cart 112. In this manner, the user devices 105 may connect to the third-party system(s) 135 or the backend system 130, via the communication case 110 or the communication cart 112 over available modes 115.

Generally, as discussed herein, the communication case 110 may include at least: a case with a sealed compartment; a battery within the sealed compartment; a modem within the sealed compartment and powered by the battery; and a WIFI transceiver within the sealed compartment and powered by the battery. The modem and WIFI transceiver may connect external user devices 105 to endpoints over available wireless communication channels of the modes 115. Moreover, as discussed herein, a communication cart 112 may include: a communication compartment with at least a modem and a WIFI transceiver to connect user devices 105 to endpoints over available wireless communication channels of the modes 115; a sanitization station; and a set of wheels for maneuvering the communication cart 112. The sanitization station may include a sanitization system configured to sanitize a user device 105.

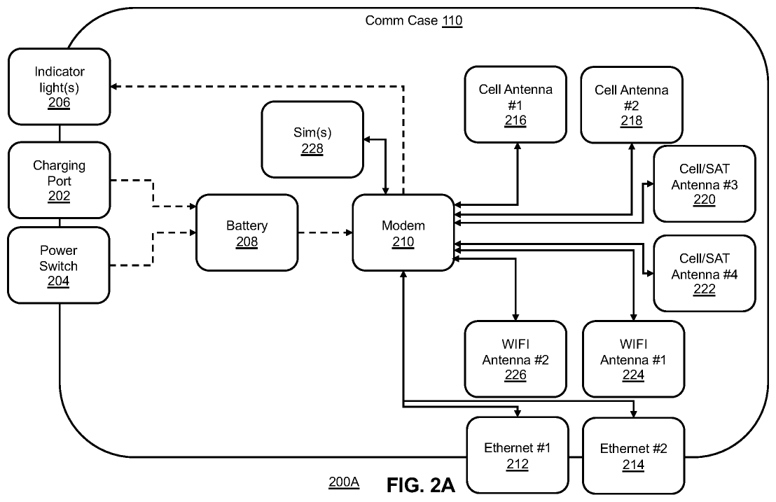

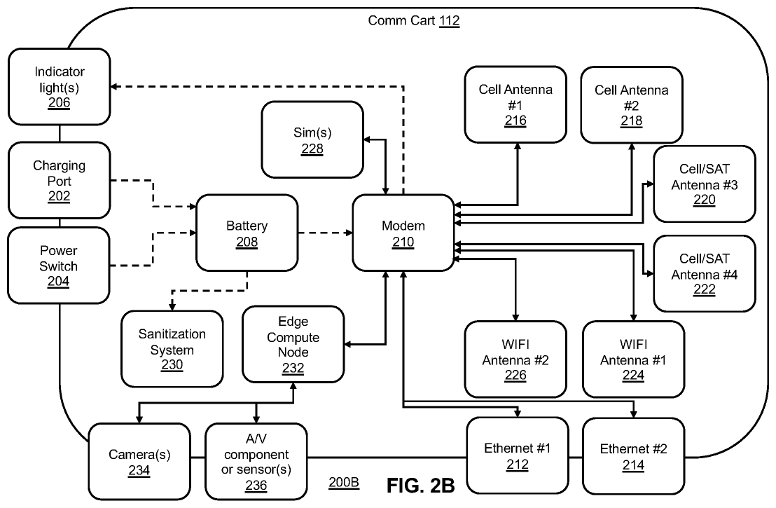

The modes 115 may include zero, at least one, or a plurality of cellular networks, such as first cellular network 120A, a second cellular network 120B, to a Nth cellular network 120N. The modes 115 may include zero, at least one, or a plurality of WIFI networks, such as first WIFI network 125A, to Nth WIFI network 125N. The modes 115 may include zero, at least one, or a plurality of SAT networks, such as first SAT network 123A, to Nth SAT network 123N. Each cellular network may have one to a plurality of cell nodes (e.g., cell towers, micro-cells, and the like) that transmit and receive data packets to/from cellular modems, such as modem 210 (see FIGS. 2A and 2B), via antennas of cellular modems. Similarly, each SAT network may have one to a plurality of satellite nodes (e.g., satellite communication nodes, ground nodes, and the like) that transmit and receive data packets to/from SAT/cellular modems, such as modem 210 (see FIGS. 2A and 2B), via antennas of SAT/cellular modems. Similarly, each WIFI network may have one to a plurality of WIFI nodes (e.g., routers, WIFI points, and the like) that transmit and receive data packets to/from WIFI transceivers, such as a part of modem 210 (see FIGS. 2A and 2B), via WIFI antennas of modems. For a given location, each cellular network, SAT network, and/or WIFI network may have a similar or different signal characteristic (e.g., signal strength/quality). For instance, the signal characteristic may be (or based on) one or combinations of: (1) signal-to-noise ratio (SNR), (2) reference signal received power (RSRP), (3) reference signal received quality (RSRQ), and/or (4) received signal strength indicator (RSSI). Generally, the modem 210 may determine available networks as available wireless communication channels, determine the signal characteristics of the available networks, and select one or more wireless communication channels to initiate communication over with the selected channels. After a selected wireless communication channel is selected, the modem 210 may relay data packets between a connected user device to the selected one or more channels. The cellular networks, SAT networks, and WIFI networks may relay the data packets to endpoints (e.g., over the internet, private networks, enterprise networks, and the like), such as the backend system 130 and/or the third-party system(s) 135.

The backend system 130 may be a management system for the communication cases 110 and the communication carts 112. In some cases, the management system may own the communication cases 110 and the communication carts 112 and allow certain organizations/enterprises/individuals use the communication cases 110 and the communication carts 112, while managing the communication cases 110 and the communication carts 112. In some cases, the management system may manage the communication cases 110 and the communication carts 112 for the certain organizations/enterprises/individuals that use the communication cases 110 and the communication carts 112. The backend system 130 (automatically or via, e.g., engineers associated the management system) may manage software and/or configurations of the communication cases 110 and the communication carts 112. The configurations may change settings, access rules, wireless communication processes, and the like. The software may be, for example, firmware patches or (in the case of an edge compute node) applications for use by an end user. Thus, the communication cart 112 or communication case 110 may be updated without having to be returned to a facility (e.g., associated with the management system), thereby extending useful life, increasing security, or adding or modifying software functionality.

In some cases, as discussed herein, the backend system 130 may include a SIM injector 132 (remote from the communication cart 112 or the communication case 110). The SIM injector 132 may manage a plurality of SIM cards, with each one having remote SIM data that can be used on a remote SIM in a modem 210. The plurality of SIM cards may include, for instance, 24, 48, or any suitable number of SIM cards. The SIM injector 132 may transmit (over an existing communication channel) remote SIM data for one SIM card to a modem 210 of a communication cart 112 or communication case 110, and the modem 210 may load a remote SIM with the virtual SIM data, so that the modem 210 may access additional cellular networks that are not currently accessible to the modem 210. Thus, the communication cart 112 or communication case 110 may be modified to access cellular networks not available (or in a different manner than currently existing on) the modem 210, thereby extending useful geographic regions and cellular networks the communication cart 112 or communication case 110 may operate in for end users.

The third-party system(s) 135 may include any other system accessible by the internet, or designed endpoints, such as those associated with the organizations/enterprises/individuals that use the communication cases 110 and the communication carts 112. In some cases, one or more of the third-party system(s) 135 may be associated with medical devices to provide server-side processing for patient monitoring applications, medical data entry applications, telehealth applications, drug delivery applications, operating device applications, and the like. In some cases, one or more of the third-party system(s) 135 may be associated with maintenance systems or IT systems to provide server-side processing for the maintenance applications or IT applications. In some cases, one or more of the third-party system(s) 135 may be associated with presentation systems, audio/video conferencing systems, and/or learning systems to provide server-side processing of presentation applications, audio/video conferencing applications, and/or learning applications. In some cases, one or more of the third-party system(s) 135 may be associated with XR devices to provide server-side processing for virtual reality applications, augmented reality applications, mixed reality applications, and the like.

Therefore, as discussed herein, the present disclosure may provide communication connectivity between various user devices to various endpoints, via a selected wireless communication channel. In this manner, a selected mode may ensure connectivity, regardless of the location of the communication case 110 or communication cart 112.

In addition, in the case of the communication case 110, the connectivity is provided via hardware inside a sealed compartment, which reduces the spread or persistence of infectious material (e.g., COVID-19, and the like). Moreover, in the case of the communication cart 112, the connectivity is provided via hardware that has a sanitization station nearby to sanitize a user device, e.g., between uses.

In addition, as discussed herein, both the communication case 110 and communication cart 112, provide resilient connectivity that covers multi-path communication and/or fail-over communication, thus connectivity is efficient/timely (in the case of multi-path) or ensured (in the case of fail-over) even in the case of localized connectivity issues of a local infrastructure. For instance, if WIFI of a local infrastructure is not adequate (e.g., because a building has too many and/or too thick walls to transmit WIFI signals, or the WIFI nodes are not sufficiently dispersed for coverage) or disrupted for a transient reason (e.g., construction or natural disaster), the communication case 110 or the communication cart 112 may route data packets via cellular communication (e.g., securely using VPN).

Block Diagrams

FIGS. 2A and 2B depict block diagrams 200A and 200B schematically showing a communication case 110 and a communication cart 112. Generally, reference numbers refer to same or similar components, with differences noted when relevant.

Communication Case Block Diagram

Diagram 200A depicts a communication case 110 adopted for exposure to biological material. The block diagram 200A showing the communication case 110 applies to the communication case 110 as described above with respect to FIG. 1. The communication case 110 may include at least a modem 210 and a battery 208 sealed in a sealed compartment. The sealed compartment may be configured to seal the modem 210 and battery 208 to ensure users or biological material cannot interact with the modem 210 or battery 208, as electronics, such as modem 210 or battery 208, are difficult to sanitize. In this manner, the communication case 110 may provide network connectivity, while decreasing transference of biological material. For instance, the communication case 110 may connect to user devices 105 via WIFI or ethernet on an exterior of the case 110, and provide connectivity access to endpoints from within the sealed compartment. In one aspect, the modem 210 includes cellular antennas and WIFI antennas within the sealed compartment as well, thereby only presenting certain ports, lights, or switches on an exterior of the case 110 or outside the sealed compartment. In this manner, difficult to sanitize components are within the sealed compartment, while relatively easier components to sanitize are exposed to an environment (e.g., a power switch or indicator light).

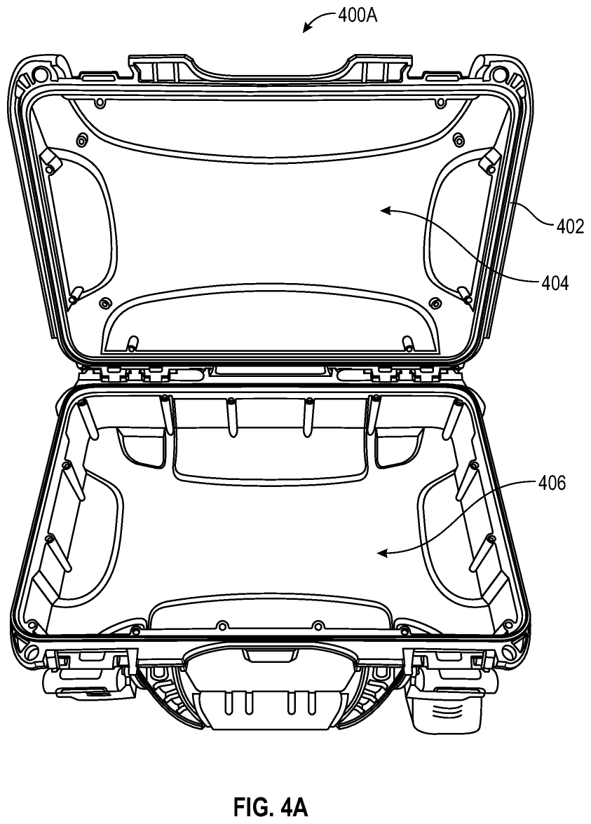

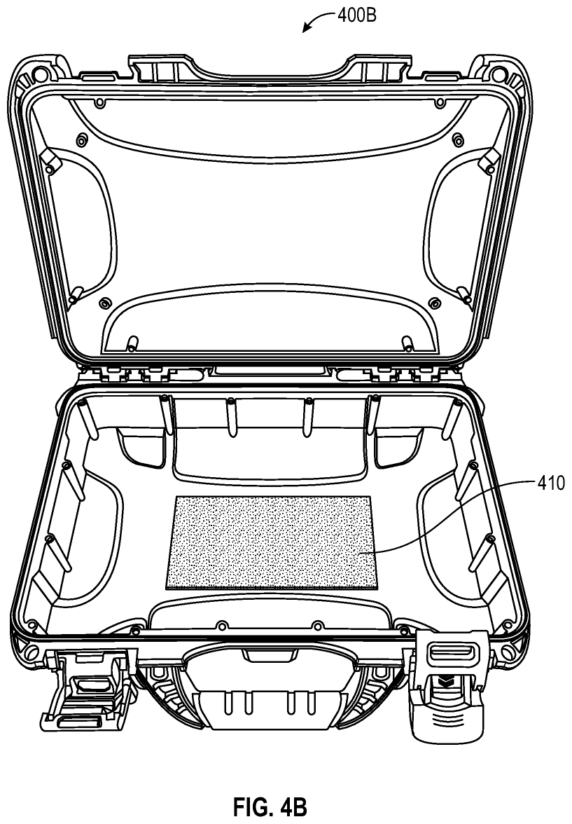

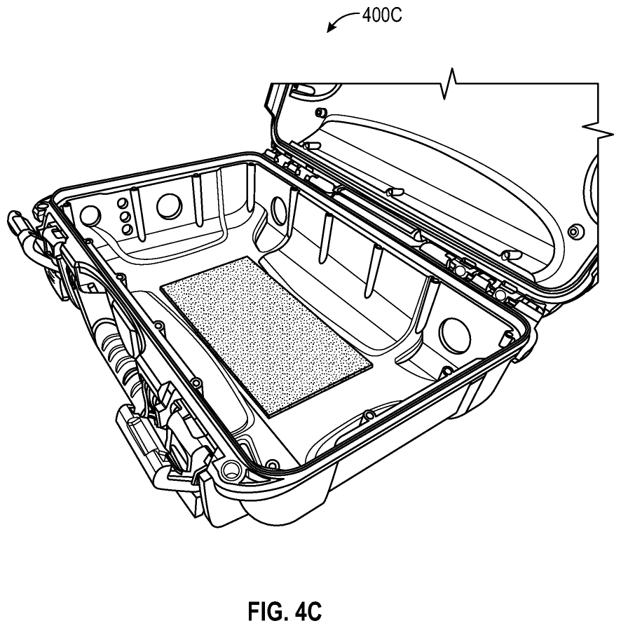

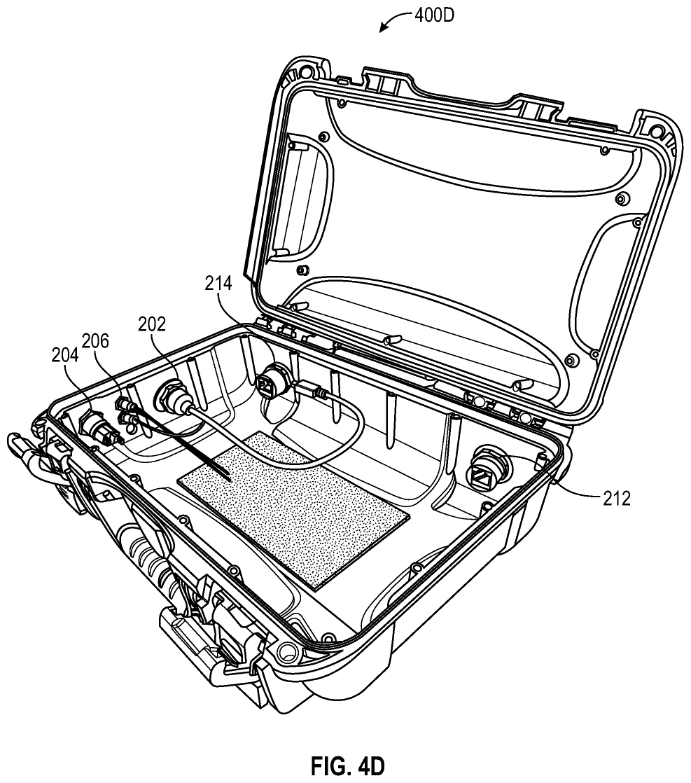

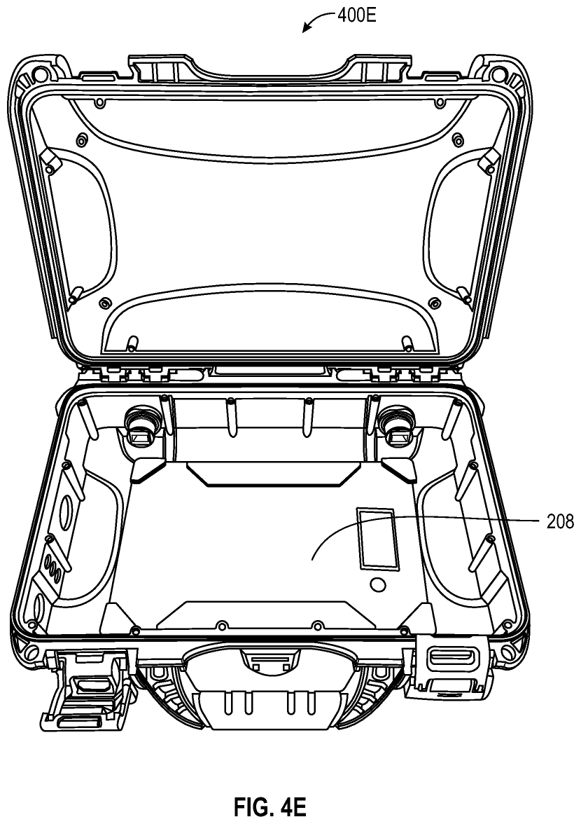

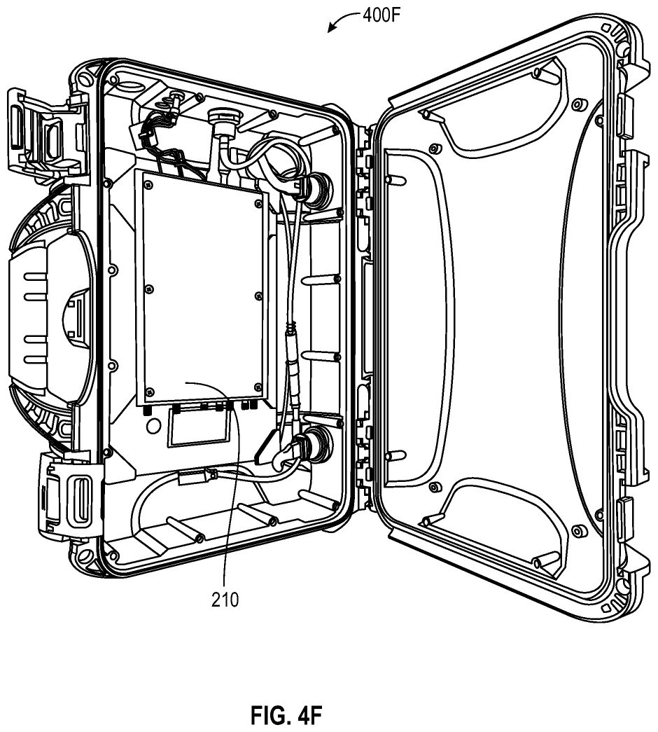

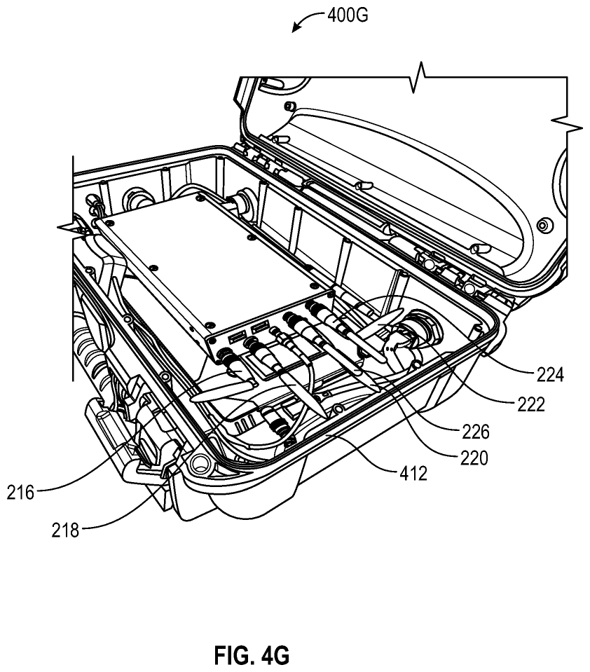

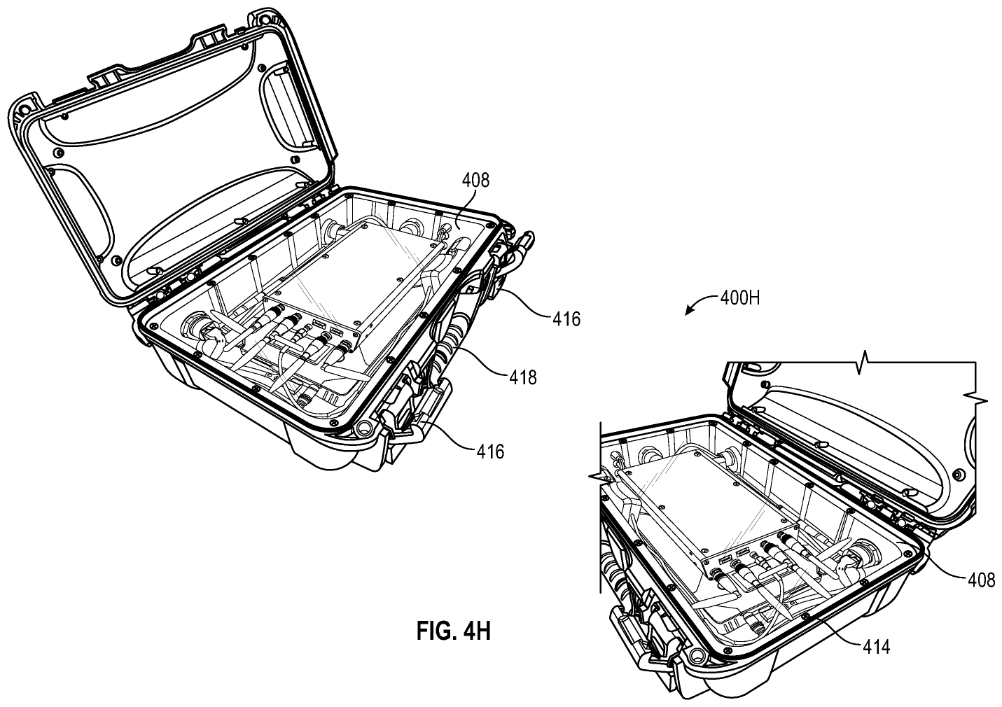

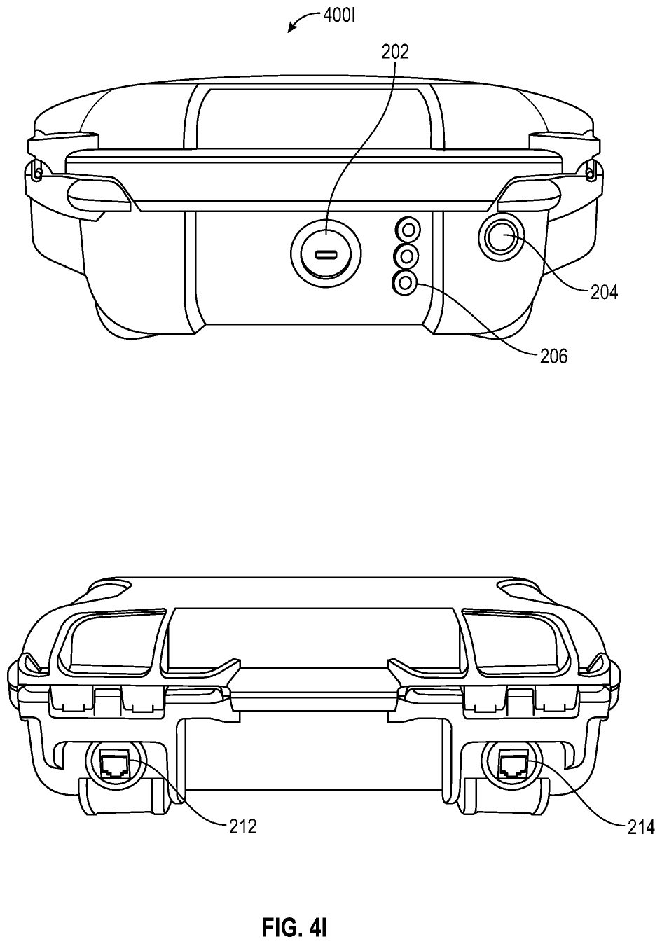

In some cases, the communication case 110 includes a case 402 (see FIG. 4A). The case 402 may be formed, generally, of non-metallic materials. In some cases, the case 402 maybe formed of anti-microbial plastics, polycarbonate, acrylic, carbon fiber, plastics, ABS, PVC, Teflon, and/or general polymers. The case 402 may include two compartments 404 and 406 (see FIG. 4A) within an interior volume of the case 402. The case may be configured to be opened to provide access to a first compartment 404 of the two compartments.

In some cases, the communication case 110 includes a panel 408 (see FIG. 4H). The panel 408 may be positioned to separate a sealed compartment 406 of the two compartments within the case 402 from the first compartment 406. The panel 408 may seal the sealed compartment 406 from an exterior of the case 402 and from the first compartment 404. The panel 408 may be formed, generally, of non-metallic materials. In some cases, the case 402 maybe formed of anti-microbial plastics, polycarbonate, acrylic, carbon fiber, plastics, ABS, PVC, Teflon, and/or general polymers. The panel 408 may be transparent (e.g., to radio frequency waves and/or visual spectrum light).

The modem 210 may have cellular, SAT, and/or WIFI transceiver components that are connected to a plurality cellular or SAT antennas (such as cell antenna #1 216, cell antenna #2 218, cell/SAT antenna #3 220, and cell/SAT antenna #4 222) and a plurality of WIFI antennas (such as WIFI antenna #1 224 and WIFI #2 226), via a set of antenna terminals. In some cases, the modem 210 includes satellite transceiver components that are connected to satellite antennas to provide connectivity via satellite communication systems. In some cases, the cellular, SAT, and WIFI antennas may be within the sealed compartment. In some cases, the cellular and WIFI antennas may be within the sealed compartment, while the SAT antenna(s) may be outside the sealed compartment. For instance, the SAT antenna(s) may be attached to an interior of the first compartment 404 (e.g., mounted on the lid or panel 408) or on an outside of the case 402. In the case the SAT antenna(s) are outside the sealed component, the panel 408, the lid, or the walls of the sealed compartment may include one or more antenna cable port(s). The one or more antenna cable port(s) may be connected to the SAT antenna(s) by antenna cables (on an exterior side of the sealed compartment) and connected to the modem 210 by antenna cables (on the interior side of the sealed compartment). In some cases, the modem and/or SAT antennas may be powered by the battery 208 or an external power source (e.g., via charging port 202). The battery 208 may provide power to the modem 210, so that the modem 210 may connect user devices 105 to one or more available modes of the modes 115.

To access and use available modes of the modes 115, the modem 210 may have SIM(s) 228. The SIM(s) 228 may include one, two, three, four, or a plurality of SIM cards (e.g., 8, 16, and the like). Each SIM card of the SIM(s) 228 may be a network SIM, an electronic SIM, or a remote SIM injected across a network. A network SIM may allow the modem to access a particular cellular network (e.g., Verizon®, AT&T®, and the like). An electronic SIM may digitally host similar information for one or a plurality of networks. A remote SIM may receive remote SIM data for one SIM card of a remote SIM injector 132 (over an existing available mode). The modem 210 may load the remote SIM with the virtual SIM data, and then the modem 210 may access additional cellular network(s) (that correspond to the remote SIM data) that are not currently accessible to the modem 210.

In some cases, the modem 210 may be configured to determine wireless communication channels for cellular networks and/or WIFI networks available at a location of the case 202. For instance, the modem 210 may evaluate reference signals received from various networks (cellular or WIFI) within range of the modem 210. The modem 210 may then determine signal characteristics of available cellular networks and/or WIFI networks. For instance, the modem 210 may determine one or more of SNR, RSRP, RSRQ, and/or RSSI for the networks within range of the modem 210. The modem 210 may then select a wireless communication channel as a first wireless communication channel from among the available cellular networks and/or WIFI networks based on the signal characteristics of each channel. For instance, the modem 210 may determine a wireless channel that has a best bandwidth, strongest signal strength for communication, a lowest latency, and the like, or combination thereof, and select a channel based on selection criteria (e.g., set by configurations). The modem 210 may then relay data packets between the user device 105, when the user device 105 is connected to an ethernet port 212 or the WIFI transceiver, and the endpoint via the selected wireless communication channel. For instance, the modem 210 may transmit data packets from the user device 105 to the endpoint via the channel and transmit data packets from the endpoint, via the channel, to the user device 105.

In some cases, the communication case 110 may include one or more (e.g., two, three, a plurality) ethernet ports (such as ethernet #1 212 and ethernet #2 214). The ethernet ports may be disposed on an exterior of the sealed compartment to provide an ethernet connection on an interior of the sealed component and be connected to ethernet ports on the modem 210. In this manner, user devices 105 may connect via an ethernet cable to the modem 210 of the communication case 110 and connect securely to endpoints. In some cases, the user devices 105 (e.g., sensitive medical devices, sensitive military devices, etc.) that may not have WIFI connectivity (e.g., to reduce security exposure), may connect via an ethernet cable to the modem 210 of the communication case 110 and connect securely to endpoints (e.g., via VPNs).

In some cases, a user device 105 may be connected to a first ethernet port or via WIFI connection to the modem 210, and the modem 210 may relay data packets across one or more selected modes. In some cases, the one or more selected modes may include wireless communication channels (e.g., of the modes 115) and also wired networks via a second ethernet port of the communication case 110. For instance, the second ethernet port may be connected to a local ethernet network (e.g., a WAN to the communication case 110), a second communication case 110 (via an ethernet port of the second communication case 110 or WIFI network of the second communication case), a communication cart 112, or to an exterior cellular modem (e.g., a cellular phone, a cellular modem device, and the like). In this manner, data packets may be distributed over multiple modes of communication, duplicated over multiple modes of communication, or the multiple modes may be failsafe/redundancy options in case of a selected (e.g., preferred) communication mode fails (or reduces signal characteristics). Generally, the configurations (set, e.g., remotely, by the management system) may indicate how the modem 210 is to manage data packets, based on connectivity circumstances. For instance, the configuration may prioritize distributed or duplicative data packet delivery over redundancy (thereby ensuring delivery at transmission cost or bandwidth utilization). Various tradeoffs may be made between the available configurations, and the modem 210 may re-configured based on changes in situation (e.g., based on request or over time). In this manner, the communication case 110 may manage data packets for a user device 105 in an efficient manner (in the case of distributive or redundant set ups), in a high-confidence manner (in the case of duplicative set ups), or in a cost-sensitive manner (e.g., redundant set ups selecting lower cost communication that is sufficient to transfer required communication bandwidth)

In some cases, a plurality of communications cases 110 may be connected together, via ethernet daisy-chaining or WIFI network connections. A managing communication case 110 (e.g., based on vote, first to act, serial number, and the like principles) or the backend system 130 may manage the plurality of communication case 110 and combine bandwidth of the plurality of communication cases 110 over different modes 115. The managing communication 110 or backend system 130 may appropriation or aggregate the combined bandwidth to one or sets of the plurality of communication cases 110. In this manner, data packet management for several user devices 105 may be intelligently managed over several communication cases 110, if the communication cases 110 are close enough to connect via ethernet or WIFI networks.

In some cases, the communication case 110 may include a charging port 202. The charging port 202 may be disposed on an exterior of the case 402. The charging port 202 may provide a charging connection on an interior wall of the case 402 in the sealed compartment 406.

In some cases, the communication case 110 may always be on (if the battery 208 has sufficient charge and/or is connected to a charger, via the charging port 202). In this case, the communication case 110 may be powered on and ready to connect to a user device and provide connectivity to one or more modes 115.

In some cases, the communication case 110 may include a power switch 204. The power switch 204 may be disposed on an exterior of the case 202. The power switch 204 may be coupled to the modem 210. A user may operate the power switch 204 to initiate a first wireless communication channel and a second communication channel. The first wireless communication channel may be between the modem 210 and a cellular node (of a cellular network, such as the first Cell Network 120A, via an antenna, such as the cell antenna #1 216). The second communication channel may be between the WIFI transceiver (of the modem 210) and a user device 105, external to the sealed compartment 206, without accessing an interior of the sealed compartment 206 and without disrupting the seal. Therefore, in some cases, the power switch 204 may initiate connectivity (e.g., when a user wants it), thereby enabling relay of data packets between an endpoint and the user device 105.

In some cases, the communication case 110 may include indicator light(s) 206. For instance, the communication case 110 may include one, two, three, or a plurality of indicator lights 206. As depicted, in FIG. 4I, the communication case 110 may include three indicator lights 206. Each indicator light 206 may provide at least one indicator connection on the interior wall of the case 402 in the sealed compartment 406. The modem 410 may include at least one indicator output connected to the at least one indicator connection. In some cases, the modem 210 may be configured to, after connecting with the endpoint, cause the at least one indicator light 206 to indicate the communication case 110 is ready for communication. In some cases, the indicator light(s) 206 may include a first indicator light and a second indicator light, where the first indicator light indicates the modem 210 is powered on, and the second indicator light indicates the modem 210 is connecting and/or connected to the endpoint. In some cases, the power switch 204 may also include an indicator light to indicate the switch is on and the battery 208 has charge.

In some cases, the panel 408 may hermetically seal the sealed compartment 406 from the exterior of the case 402 and from the first compartment 404. In some cases, the panel 408 may prevent liquids from entering/exiting the sealed compartment 406. In some cases, the panel 408 may prevent air and liquids from entering/exiting the sealed compartment 406.

In some cases, the modem 410 includes: (1) at least two SIMs including a first SIM and a second SIM in the SIM(s) 228, and (2) a plurality of antenna terminals for a plurality of antennas including at least two cellular antennas. In some cases, the number of SIMs in SIM(s) 228 may be more or less than two. The number of cellular antennas may be more or less than two cellular antennas, such as four, six, eight, sixteen, and the like.

In some cases, the plurality of antennas include sets of paired antennas. For instance, each set of paired antennas include a primary (e.g., a main) antenna and an auxiliary antenna. In some cases, each of the paired antennas may be orthogonally orientated with respect to another of the paired antennas within the sealed compartment 206. The modem 210 may use the pairs of primary and auxiliary antennas for certain SIM cards, or the SIM cards may be dynamically (e.g., programmatically or by configuration by the management system) assigned to antennas.

In some cases, the plurality of antennas include terminal mounted antennas. In some cases, the terminal mounted antennas are monopole antennas. For instance, the terminal mounted antennas may be less 100 mm.

In these cases, the terminal mounted antennas may fit in an air gap between the modem 210 and an interior wall of the case 202.

In some cases, the plurality of antennas may include (a) a phased antenna array and/or (b) PCB antennas and/or flex antennas. The phased antenna array may include at least two antennas controlled via software to change a shape and direction of the radiation pattern without physically moving the antenna. Elements in the antenna array may be placed in such a way that the signals transmitted by individual antennas of the phased antenna array sum up and provide better gain, directivity and performance in a particular direction, in accordance with the control software. For instance, the control software may cause individual antennas of the phased array to transmit signals of a same frequency from all the individual elements in the array but with a certain phase difference/shift between each antenna element in the array. The phase shift may be calculated to provide constructive interference in a desired direction while destructive interference may occur in other directions. The PCB antennas and/or flex antennas may be mounted on the panel 408 in the sealed compartment 406, on sides of the modem 410, or on interior walls of the case 202 in the sealed compartment 406.

In some cases, the modem 210 is configured to switch wireless communication channels when signal characteristics change. In some cases, the modem 210 is configured to switch wireless communication channels when: (1) a change is detected while periodically redetermining signal characteristics, (2) a signal characteristic of the selected wireless communication channel falls below a threshold, or (3) detect the communication case 110 has moved more than a threshold distance. For instance, the modem 210 may re-determine signal characteristics every set period of time (e.g., five seconds) or when new data packets are relayed (in or out). The threshold may be a default value or set by the configuration (e.g., by the management system). In some cases, the modem 210 may receive location data from the cellular network (e.g., cell node ID is at first location, modem 210 is located relative to cell node first location) or from a GPS system (e.g., in modem 210). The threshold distance may be a default value (e.g., five meters) or dynamically set.

In some cases, the modem 210 is configured to switch wireless communication channels when data use of the selected wireless communication channel crosses a threshold for a period of time. For instance, the modem 210 may track data use (e.g, in MBs or GBs) over a given channel and switch when a threshold is crossed (e.g., 2 GB, or as set by configurations by the management system).

In some cases, the charging port 202 and the charging connection may be USB-C compatible. For instance, this may enable the communication case 110 to be charged with readily available charging system, instead of specialized charging system. In some cases, the charging port 202 may be AC outlet compatible (e.g., with an AC outlet and/or power block to convert to DC power), or DC outlet compatible (e.g., with a DC outlet of various standards).

In some cases, the modem 210 is configured to auto-boot when the power switch 204 is operated by a user. The power switch 204 may be configured to provide power from the battery 208 to the modem 210. The modem 210 may then determine available networks and select a channel to communicate, even if a user device 105 is not yet connected to the modem 210.

In some cases, the battery 208 is positioned on a bottom of the sealed compartment 206. In some cases, the battery 208 and the modem 210 are stacked on a bottom of the sealed compartment 206. In some cases, the modem 210 is stacked on top of the battery 208.

In some cases, the ethernet ports (e.g., 212 and 214) may be disposed on a first exterior wall of the case 402 and the charging port 202 is disposed on a second exterior wall of the case 402. In some cases, the charging port 202 and the at least one indicator light 206 may be on same exterior wall of the case 402. In some cases, the plurality of antennas are positioned away from the ethernet port, the charging port 202, and/or the at least one indicator light 206.

In some cases, the first compartment 404 is configured to hold a charging cable and/or a charger compatible with the charging port 202 and the charging cable. In some cases, the first compartment 404 is configured to hold disinfecting supplies. Thus, the communication case 110 may house disinfecting supplies to clean the communication case 110 and/or a charging cable/charger to charge the communication case 110.

In some cases, the case 402 includes a ledge 412 to receive the panel 408. In some cases, the communication case 110 may include a seal (e.g., a gasket and the like) between the panel 408 and the ledge 412 of the case 402 to hermetically seal the sealed compartment 406. In some cases, the panel 408 is affixed to the ledge 412 via a plurality of fasteners 414.

In some cases, the communication case 110 includes a handle 418 and a latch 416 (see FIG. 4H). The latch 416 may lock and unlock the case 402 to open the first compartment 404. The handle 418 may enable a user to carry the communication case 110.

In some cases, the battery 208 is an always on battery if it has sufficient charge. For instance, an always on battery may not turn off if it senses current draw from loads (e.g., the modem 210). Thus, the battery 208 may be available to provide power even if the power switch 204 is in an off state or the modem 210 is turned off (and not drawing power) or a sleep (and drawing a sleep amount of power).

In some cases, the battery 208 is configured to, after being depleted and recharged, provide a set power delivery instead of a default value. For instance, the voltage output of the battery 208 may be set to an amount appropriate power delivery for the modem 210 and not a default value, and the battery 208 may store and re-configure itself after being recharged to provide the appropriate power delivery.

Communication Cart Block Diagram

Diagram 200B depicts a communication cart 112. The block diagram 200B showing the communication cart 112 applies to the communication cart 112 as described above with respect to FIG. 1. The communication cart 112 may include the same or different features from the communication case 110. For instance, in some cases, the communication cart 112 may include similar functional components (e.g., modem 210, antennas 216-226, ethernet ports 212 and 214, SIM(s) 228, battery 208, charging port 202, power switch 204, and indicator light(s) 206), but not have a same form factor as the communication case 110. Instead, the communication cart 112 may have a set of wheels 502, a communication compartment 506, and a sanitization station 504. In other cases, the communication cart 112 may have less functional components than the communication case 110. For instance, the communication cart 112 may omit a battery 208 and the like, and instead connect to an AC outlet for power. Other differences will be noted below, but the communication cart 112 and the communication case 110 may have various other differences (e.g., different numbers of antennas, different types of antennas, different number of outputs/input (such as ethernet) and the like).

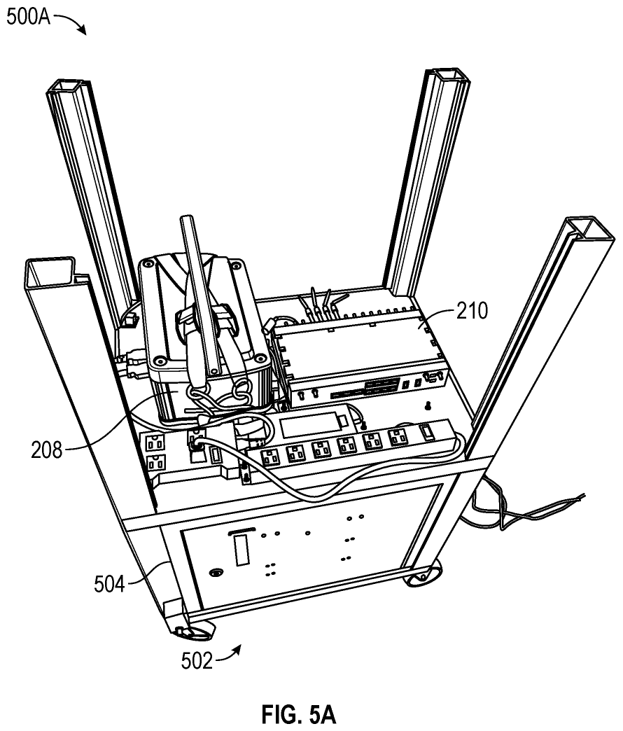

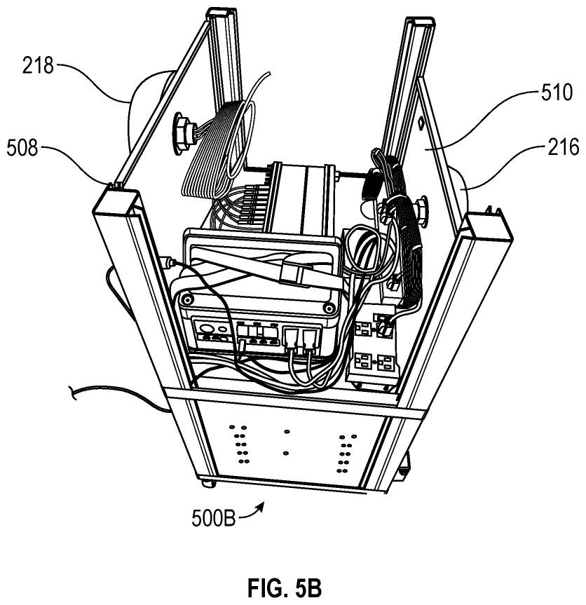

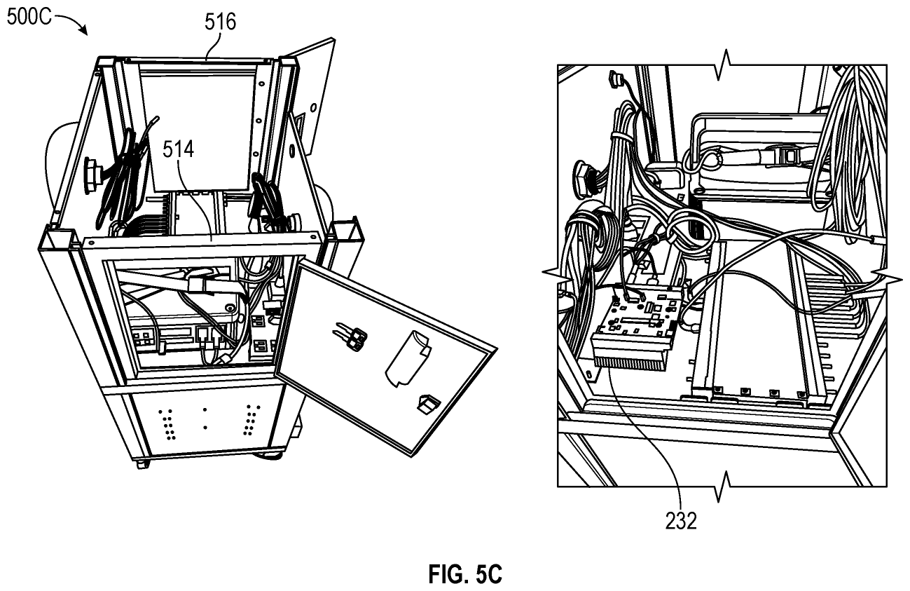

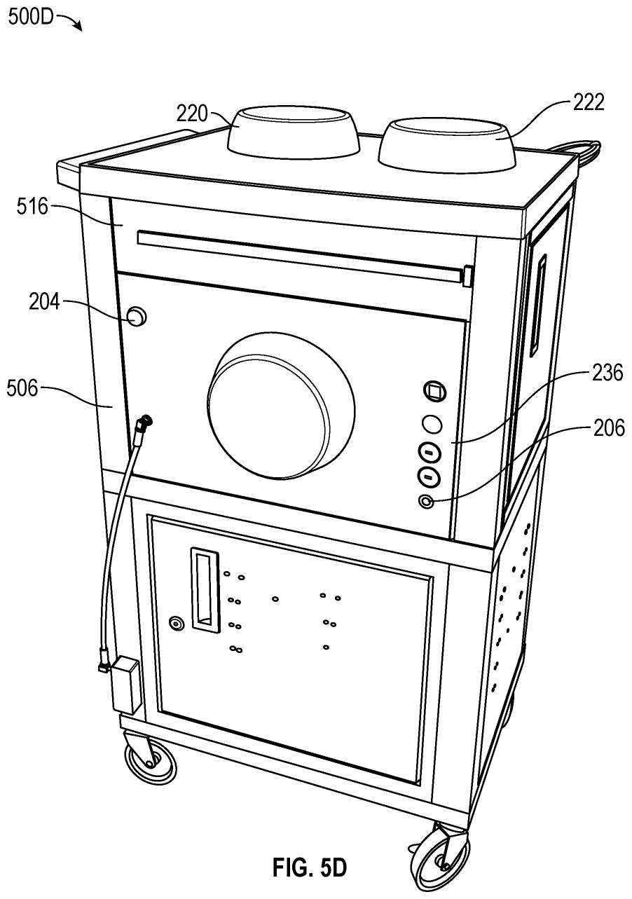

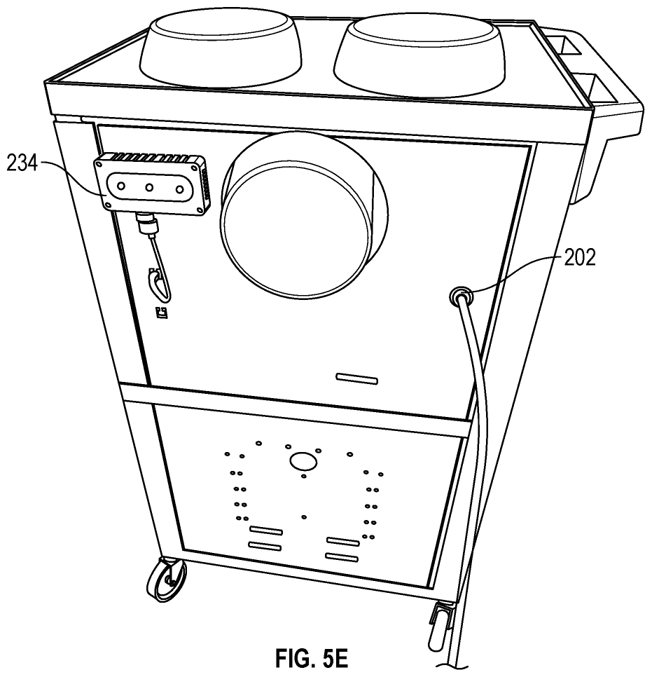

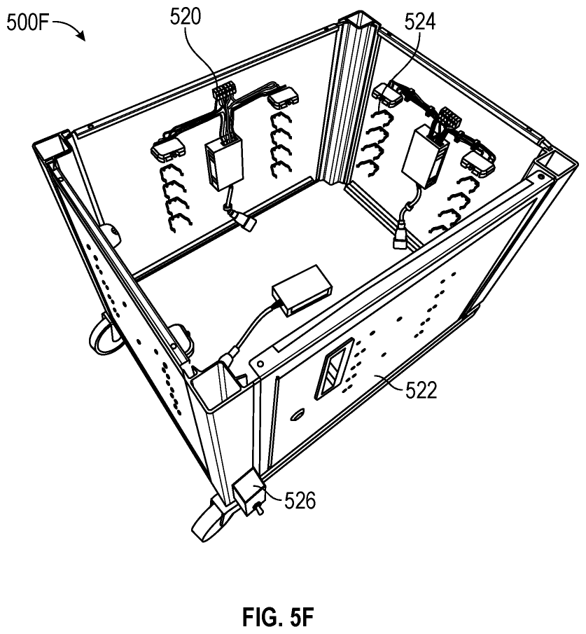

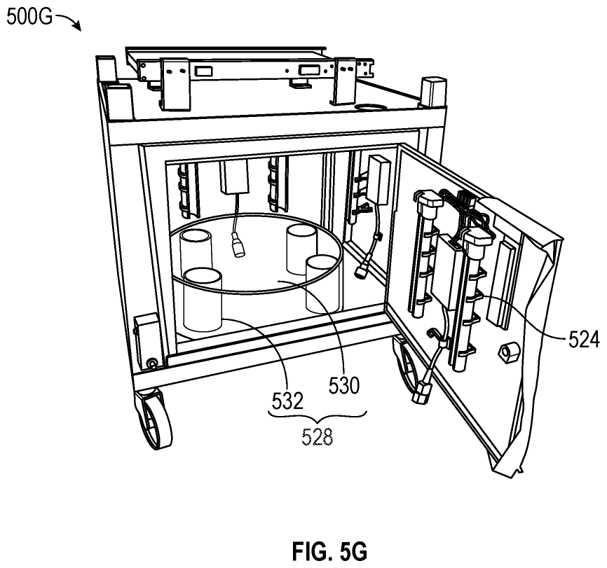

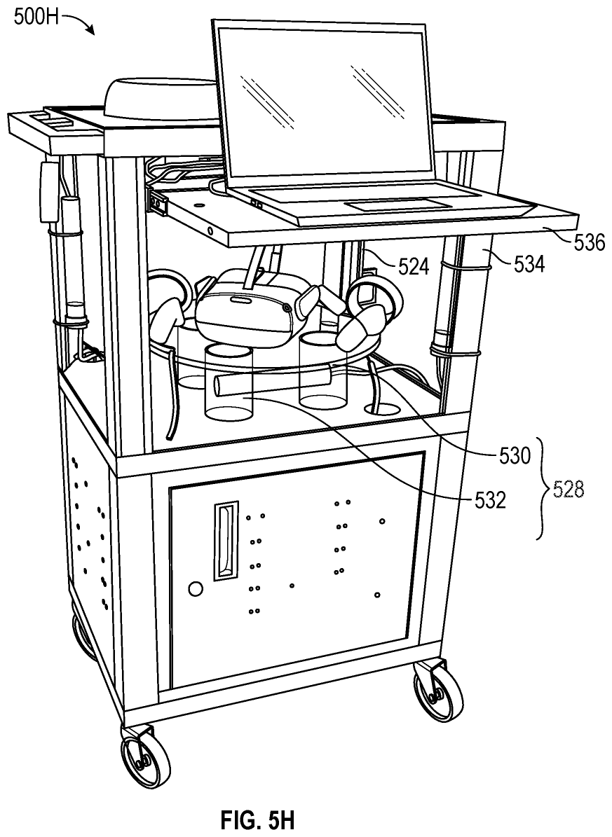

The communication compartment 506 may include front and back walls 508 and 510, side walls 512 and 514, and a top 516 (see FIGS. 5A-5E). The communication compartment 506 may have one or more doors (e.g., in the side walls 512 and 514).

In some cases, the communication cart 112 may include a sanitation system 230. The sanitation system 230 may be a UVC system or a far UV system. In some cases, the sanitization station 504 is a sanitization compartment (see FIG. 5A) that may have side walls 520 and a door 522, with the door 522 configured to be opened and closed. The sanitization compartment may be sealed when closed.

In some cases, the sanitization station 504 includes a sanitization switch 526 disposed on an exterior of the sanitization compartment. The sanitization switch 526 may be coupled to the sanitization system, so that when the user operates the sanitization switch 526 the sanitization system starts a sanitization process of the sanitization system. In some cases, the sanitization system is always on and the sanitization switch 526 may be omitted.

In some cases, the sanitization station 504 includes a platform 528 positioned in a zone of the sanitization station 504 and configured to hold the user device 105. The platform may be transparent to germicidal wavelengths of electromagnetic radiation (e.g., short-wave UV, 100 to 280 nanometer wavelength light). For instance, the platform 528 is transparent to ultraviolet radiation having 222 or 254 nanometer wavelength light. The platform 528 may have a surface 230 configured to hold the user device and supports 528 configured to position the surface above a bottom of the sanitization station 504 in the zone.

In some cases, the sanitization system 230 includes a plurality of ultraviolet radiation lamps 524 and a platform 528 positioned in a zone of the sanitization station 504 and configured to hold the user device. The plurality of ultraviolet radiation lamps 524 may be disposed on interior walls of the sanitization compartment.

In some cases, the plurality of ultraviolet radiation lamps 524 may radiate the platform 528 from at least two sides of the platform. The at least two sides of the platform may be opposite each other.

In some cases, the plurality of ultraviolet radiation lamps 524 may radiate the platform 528 from four orthogonal sides of the platform 528. In some cases, the plurality of ultraviolet radiation lamps 524 radiate the platform 528 from above and below the platform 528.

In some cases, the sanitization compartment includes reflective material on interior walls of the sanitization compartment. The reflective material may reflect UV light to increase angles of attack on the user device 105 and/or block UV light from exiting the compartment.

In some cases, the sanitization system 230 is powered by the battery 208, positioned in the communication compartment. In some cases, the sanitization system 230 is powered by a separate battery (not shown). In some cases, the sanitization system 230 is powered by an AC outlet.

In some cases, the sanitization system is a far ultraviolet system. The far ultraviolet system may be configured to be always on. In some cases, the far ultraviolet system of the sanitization station 504 is positioned on top 516 or an exterior side (e.g., one of front and back walls 508 and 510, side walls 512 and 514) of the communication compartment. The far ultraviolet system may radiate ultraviolet radiation to a zone. The zone may be designated for the user to hold or pass the user device 105 through the zone so as to radiate the user device with ultraviolet radiation.

In some cases, the communication cart 112 may include an edge compute node 232. The edge compute node 232 may be positioned inside the communication compartment 506.

In some cases, the edge compute node 232 is hosted on the modem 210. In some cases, the edge compute node 232 is an edge computer positioned within the communication compartment 506 and connected to the modem 210.

In some cases, the edge compute node 232 may provide software processing on the edge, instead of at a remote server. For instance, the edge compute node 232 may serve AI applications, extended reality applications, learning applications, video conferencing applications, and/or on-edge processing applications to the user device 105.

In some cases, the communication compartment 506 may include at least one camera 234. The at least one camera 234 may be disposed on an exterior of the communication compartment 506. The at least one camera 234 may be connected to the edge compute node 232. The least one camera may include a three-dimensional camera.

In some cases, the communication compartment 506 may include at least one audio/visual component 236. The at least one audio/visual component 236 may be disposed on an exterior of the communication compartment 506. The at least one audio/visual component 236 may be connected to the edge compute node 232. The at least one audio/visual component 236 may include one or more combinations of a HDMI port, a display port, a USB port, a speaker, a projector, a display, and/or a motion sensor.

In some cases, the set of wheels 502 include motorized wheels. In some cases, the edge compute node 232 is configured to control the motorized wheels. In this case, the edge compute node 232 is configured to control the motorized wheels based on user inputs and/or sensor data indicating a sensed environment, and where the sensor data is sensed by at least one sensor 236. The at least one sensor 236 includes one or combinations of: camera(s), proximity sensor(s), motion sensor(s), an ultrasound system, a radar system, and/or a lidar system.

In some cases, the communication compartment 506 is similar in size to the sanitization station 504. In some cases, the communication compartment 506 has a same footprint as the sanitization station 504. In some cases, the communication compartment 506 and the sanitization station 504 are stacked on the set of wheels 502. In some cases, the communication compartment 506 is stacked on top of the sanitization station 504. In some cases, the sanitization station 504 is stacked on top of the communication compartment 506. In some cases, the communication compartment 506 and the sanitization station 504 are arranged laterally adjacent each other on the set of wheels 502.

In some cases, the plurality of antennas may include dome antennas disposed on an exterior of the communication compartment. The dome antennas may be evenly distributed on an exterior of the communication compartment. The dome antennas may be disposed on different exterior sides (e.g., one of front and back walls 508 and 510, side walls 512 and 514) or the top 516 of the communication compartment 506. The dome antennas may be disposed on orthogonal walls or top of the communication compartment, or opposite exterior walls.

In some cases, the plurality of antennas may include integrated antennas. The integrated antennas may be formed in a housing of the modem 210 using laser direct structuring and/or molded interconnect device processes.

Communication using a Communication Case or a Communication Cart

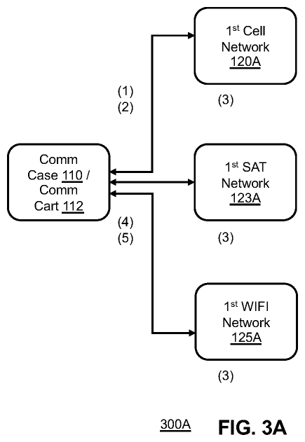

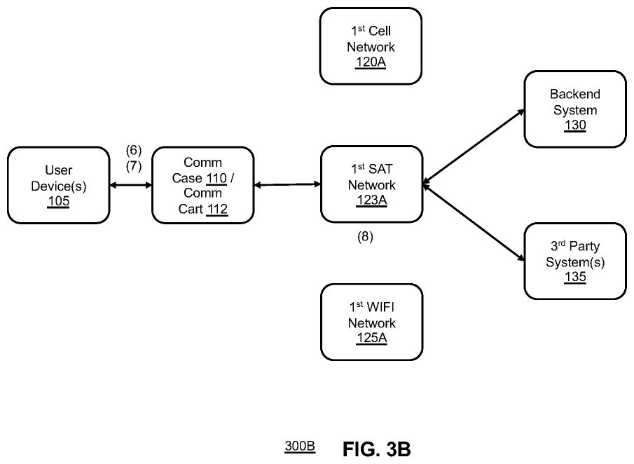

FIGS. 3A and 3B depict block diagrams 300A and 300B schematically showing a communication case 110 or a communication cart 112 selecting a wireless communication channel and relaying data packets between a user device 105 and an endpoint, via a selected wireless communication channel. The block diagrams 300A and 300B showing the communication case 110 or the communication cart 112 applies to the communication case 110 or the communication cart 112 as described above with respect to FIGS. 1, 2A, and 2B. In particular, a modem 210 of a communication case 110 or communication cart 112 may perform certain operations.

In operation (1), the modem 210 may determine available wireless communication channels. In operation (2), the modem 210 may collect reference signals from each available wireless communication channel. In operation (3), the various networks within range of the modem 210 may transmit a reference signal.

In operation (4), the modem 210 may determine signal characteristics for each wireless communication channel. In operation (5), the modem 210 may select a wireless communication channel based on signal characteristics

In operation (6), the modem 210 may detect a user device 105 is connected to ethernet port or WIFI network of the modem 210. In operation (7), the modem 210 may relay data packets between user device 105 and selected wireless communication channel (e.g., the second cell network 120B).

In operation (8), the selected channel (e.g., the first SAT network 120B) may relay data packets between com case/cart and endpoint(s).

Communication Case: Features and Manufacture

FIGS. 4A-4I depict features, and a method of manufacturing, a communication case 110. The features, and the method of manufacturing, the communication case 110 applies to the communication case 110 as described above with respect to FIGS. 1, 2A, and 3A-3B. In particular, operations to manufacture a communication case 110 are depicted to clarify arrangement and construction of the communication case 110.

In FIG. 4A, operation (1) includes obtaining case 402.

In FIG. 4B, operation (2) includes applying adhesive 410 to a bottom of case 402. The adhesive 410 may be low surface energy two part adhesive (such as provided by 3M®). In some cases, the adhesive 410 may be double sided tape or glue. In some cases, the adhesive 410 may be omitted and mechanical fixture may be used (e.g., a bracket).

In FIG. 4C, operation (3) includes generating openings in case 402. For instance, the openings may be generated with a drill, so that a power switch 204, ethernet port(s) 212 and 214, indicator light(s) 206, and charging port 202 may be installed.

In FIG. 4D, operation (4) includes installing a power switch 204, ethernet port(s) 212 and 214, indicator light(s) 206, and charging port 202.

In FIG. 4E, operation (5) includes affixing a battery 208 to case 402 using adhesive 410 (or a mechanical fixture).

In FIG. 4F, operation (6) includes affixing a modem 210 to the case 402. For instance, the modem 210 may fixed to the case 402 via the battery 208. For instance, the modem 210 may be affixed to the battery 208 via adhesive (e.g., glue and the like) or by a mechanical fastener (e.g., a bracket).

In FIG. 4G, operation (7) includes attaching antennas (e.g., 216-224) to the modem 210.

In FIG. 4H, operation (8) includes inserting panel 408 into ledge 412; and operation (9) includes affixing the panel 408 to the case 402 via fasteners 414.

In FIG. 4I, operations (10) and (11) are optional. Operation (10) includes closing the case 402. Operation (11) includes operating the power switch 204 (e.g., to test the unit).

Communication Cart: Features and Manufacture

FIGS. 5A-5H depict features, and a method of manufacturing, a communication cart 112. The features, and the method of manufacturing, the communication cart 112 applies to the communication cart 112 as described above with respect to FIGS. 1, 2B, and 3A-3B. In particular, operations to manufacture a communication cart 112 are depicted to clarify arrangement and construction of the communication cart 112.

In FIG. 5A, operation (1) includes attaching a sanitation station 504 to a set of wheels 502; and operation (2) includes affixing a battery 208 and a modem 210 to a communication compartment 506 on top of sanitation station 504.

In FIG. 5B, operation (3) includes attaching front and rear walls 508 and 510 to the communication compartment 506; and operation (4) includes attaching dome antennas 516 and 518 to walls 508 and 510 and connecting antennas to the modem 210.

In FIG. 5C, operation (5) includes attaching side walls 514 and 516 to the communication compartment 506; operation (6) includes affixing an edge compute node 232 and connecting the edge compute node 232 to the battery 208 and the modem 210; operation (7) includes attaching camera(s) 234 to an exterior of the communication compartment 506 and connecting the camera(s) 234 to edge compute node 232.

In FIG. 5D, operation (8) includes attaching a top 516 of communication compartment 506; and operation (9) includes attaching dome antennas 220 and 222 to the top 516 and connecting antennas to the modem 210.

FIG. 5E depicts camera(s) 234 and charging port 202 on communication compartment 506. FIGS. 5F,5G, and 5H depict features of sanitization station 504, including walls 520, door 522, radiation lamps 524, a platform 528, and sanitization switch 526.

In FIG. 5H, the sanitization station 504 may be above the communication compartment 506. In some cases, the sanitization station 504 may omit the walls 520 and the door 522, as the radiation lamps 524 may be far UV (e.g., safe for eye exposure). The radiation lamps 524 may be attached to columns 534 (e.g., on corners of sanitization station 504). In some cases, the radiation lamps 524 may be distributed evenly around the platform 528 (e.g., every 90 degrees in lateral directions) and/or above/below the platform 528. In some cases, the dome antennas 220 and 222 may still be attached to the top 516 of the communication cart 112, thus spaced apart from the communication compartment 506 (i.e., by the sanitization station 504). In this case, antenna wires may traverse the sanitization station 504 to connect the communication compartment 506 to the dome antennas 220 and 222 on the top 516. Moreover, the sanitization station 504 may include a second platform 536 for user devices (e.g., XR systems, laptops, medical devices or instruments, or otherwise) to rest on the cart 112 without blocking the platform 528 or the dome antennas 220 and 222. The second platform 536 may be extendable from a first position (e.g., stowed) to a second position (e.g., in use).

Example Routine(s)

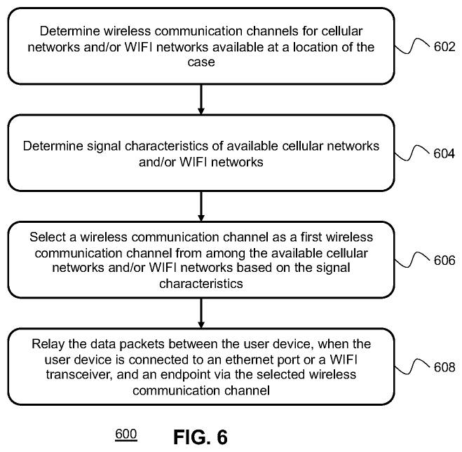

FIG. 6 depicts a flowchart of an exemplary routine 600 for selecting a wireless communication channel and relaying data packets using the selected wireless communication channel. The routine 600 applies to the communication case 110 and/or the communication cart 112, as described above with respect to FIGS. 1, 2A-2B, 3A-3B, 4A-4I, and 5A-5H. In the routine 600, operations may be performed by one or more systems, such as a modem 210, nodes of networks, and/or a user device 105.

The routine 600 may start at block 602, where the modem 210 may determine wireless communication channels for cellular networks and/or WIFI networks available at a location of the case. At block 604, the modem 210 may determine signal characteristics of available cellular networks and/or WIFI networks. At block 606, the modem 210 may select a wireless communication channel as a first wireless communication channel from among the available cellular networks and/or WIFI networks based on the signal characteristics. At block 608, the modem 210 may relay the data packets between the user device, when the user device is connected to an ethernet port or a WIFI transceiver, and an endpoint via the selected wireless communication channel.

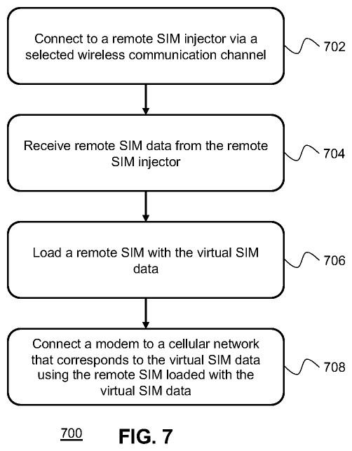

FIG. 7 depicts a flowchart of an exemplary routine 700 for injecting a remote SIM into a modem of a communication cart or a communication case. The routine 700 applies to the communication case 110 and/or the communication cart 112, as described above with respect to FIGS. 1, 2A-2B, 3A-3B, 4A-4I, and 5A-5G. In the routine 700, operations may be performed by one or more systems, such as a modem 210 and/or a backend system 130.

The routine 700 may start at block 702, where the modem 210 may connect to a remote SIM injector via a selected wireless communication channel. At block 704, the modem 210 may receive remote SIM data from the remote SIM injector. At block 706, the modem 210 may load a remote SIM with the virtual SIM data. At block 708, the modem 210 may connect a modem to a cellular network that corresponds to the virtual SIM data using the remote SIM loaded with the virtual SIM data.

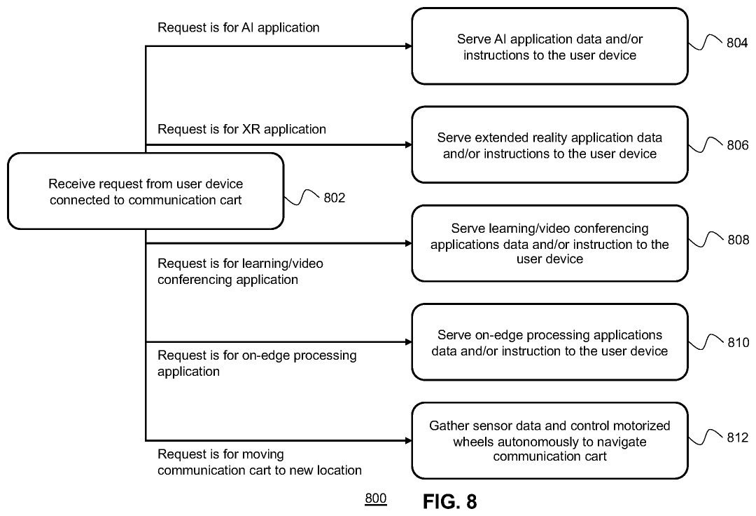

FIG. 8 depicts a flowchart of an exemplary routine 800 for serving edge node processes. The routine 800 applies to the communication cart 112, as described above with respect to FIGS. 1, 2B, 3A-3B, and 5A-5H. In the routine 800, operations may be performed by one or more systems, such as a modem 210 or an edge computer node 232. While the discussion below presents the operations as performed by the edge computer node 232, various operations may be performed by different components (e.g., a camera and the like).

The routine 800 may start at block 802, where the edge computer node 232 may receive request from user device connected to communication cart. At block 804, in the case that the request is for an AI application, the edge computer node 232 may serve AI application data and/or instructions to the user device. At block 806, in the case that the request is for an XR application, the edge computer node 232 may serve extended reality application data and/or instructions to the user device. At block 808, in the case that the request is for a learning/video conferencing application, the edge computer node 232 may serve learning/video conferencing applications data and/or instruction to the user device. At block 810, in the case that the request is for an on-edge processing application, the edge computer node 232 may serve on-edge processing applications data and/or instruction to the user device. At block 812, in the case that the request is for moving the communication cart 112 to a new location, the edge computer node 232 may gather sensor data and control motorized wheels autonomously to navigate the communication cart 112.

Computer System

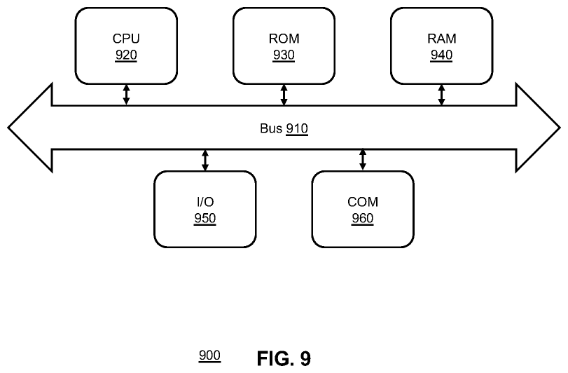

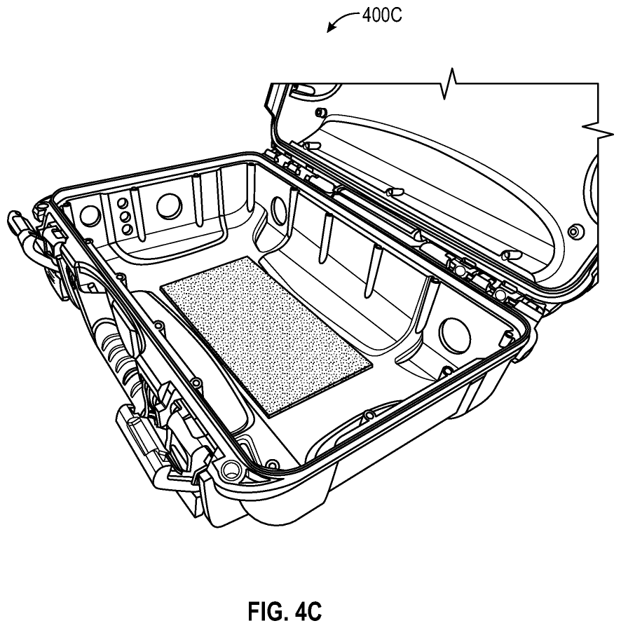

FIG. 9 depicts an example system that may execute techniques presented herein. FIG. 9 is a simplified functional block diagram of a computer that may be configured to execute techniques described herein, according to exemplary cases of the present disclosure. Specifically, the computer (or “platform” as it may not be a single physical computer infrastructure) may include a data communication interface 960 for packet data communication. The platform may also include a central processing unit (“CPU”) 920, in the form of one or more processors, for executing program instructions. The platform may include an internal communication bus 910, and the platform may also include a program storage and/or a data storage for various data files to be processed and/or communicated by the platform such as ROM 930 and RAM 940, although the system 900 may receive programming and data via network communications. The system 900 also may include input and output ports 950 to connect with input and output devices such as keyboards, mice, touchscreens, monitors, displays, etc. Of course, the various system functions may be implemented in a distributed fashion on a number of similar platforms, to distribute the processing load. Alternatively, the systems may be implemented by appropriate programming of one computer hardware platform.

The general discussion of this disclosure provides a brief, general description of a suitable computing environment in which the present disclosure may be implemented. In some cases, any of the disclosed systems, methods, and/or graphical user interfaces may be executed by or implemented by a computing system consistent with or similar to that depicted and/or explained in this disclosure. Although not required, aspects of the present disclosure are described in the context of computer-executable instructions, such as routines executed by a data processing device, e.g., a server computer, wireless device, and/or personal computer. Those skilled in the relevant art will appreciate that aspects of the present disclosure can be practiced with other communications, data processing, or computer system configurations, including: Internet appliances, hand-held devices (including personal digital assistants (“PDAs”)), wearable computers, all manner of cellular or mobile phones (including Voice over IP (“VoIP”) phones), dumb terminals, media players, gaming devices, virtual reality devices, multi-processor systems, microprocessor-based or programmable consumer electronics, set-top boxes, network PCs, mini-computers, mainframe computers, and the like. Indeed, the terms “computer,” “server,” and the like, are generally used interchangeably herein, and refer to any of the above devices and systems, as well as any data processor.

Aspects of the present disclosure may be embodied in a special purpose computer and/or data processor that is specifically programmed, configured, and/or constructed to perform one or more of the computer-executable instructions explained in detail herein. While aspects of the present disclosure, such as certain functions, are described as being performed exclusively on a single device, the present disclosure may also be practiced in distributed environments where functions or modules are shared among disparate processing devices, which are linked through a communications network, such as a Local Area Network (“LAN”), Wide Area Network (“WAN”), and/or the Internet. Similarly, techniques presented herein as involving multiple devices may be implemented in a single device. In a distributed computing environment, program modules may be located in both local and/or remote memory storage devices.

Aspects of the present disclosure may be stored and/or distributed on non-transitory computer-readable media, including magnetically or optically readable computer discs, hard-wired or preprogrammed chips (e.g., EEPROM semiconductor chips), nanotechnology memory, biological memory, or other data storage media. Alternatively, computer implemented instructions, data structures, screen displays, and other data under aspects of the present disclosure may be distributed over the Internet and/or over other networks (including wireless networks), on a propagated signal on a propagation medium (e.g., an electromagnetic wave(s), a sound wave, etc.) over a period of time, and/or they may be provided on any analog or digital network (packet switched, circuit switched, or other scheme).

Program aspects of the technology may be thought of as “products” or “articles of manufacture” typically in the form of executable code and/or associated data that is carried on or embodied in a type of machine-readable medium. “Storage” type media include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer of the mobile communication network into the computer platform of a server and/or from a server to the mobile device. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links, or the like, also may be considered as media bearing the software. As used herein, unless restricted to non-transitory, tangible “storage” media, terms such as computer or machine “readable medium” refer to any medium that participates in providing instructions to a processor for execution.

### Terminology

The terminology used above may be interpreted in its broadest reasonable manner, even though it is being used in conjunction with a detailed description of certain specific examples of the present disclosure. Indeed, certain terms may even be emphasized above; however, any terminology intended to be interpreted in any restricted manner will be overtly and specifically defined as such in this Detailed Description section. Both the foregoing general description and the detailed description are exemplary and explanatory only and are not restrictive of the features, as claimed.

As used herein, the terms “comprises,” “comprising,” “having,” including,” or other variations thereof, are intended to cover a non-exclusive inclusion such that a process, method, article, or apparatus that comprises a list of elements does not include only those elements, but may include other elements not expressly listed or inherent to such a process, method, article, or apparatus.

In this disclosure, relative terms, such as, for example, “about,” “substantially,” “generally,” and “approximately” are used to indicate a possible variation of ±10% in a stated value.

The term “exemplary” is used in the sense of “example” rather than “ideal.” As used herein, the singular forms “a,” “an,” and “the” include plural reference unless the context dictates otherwise.

### Examples

Clause 1. A communication case adopted for exposure to biological material, the communication case may include: a case, wherein the case includes two compartments within an interior volume of the case, wherein the case is configured to be opened to provide access to a first compartment of the two compartments; a panel, wherein the panel is positioned to separate a sealed compartment of the two compartments within the case from the first compartment, and wherein the panel seals the sealed compartment from an exterior of the case and from the first compartment; a modem position within the sealed compartment and powered by a battery (sealed within the sealed compartment) or an external source (connected to the case by a port, such as a charging port); a WIFI transceiver positioned within the sealed compartment and powered by the battery or the external source; and a power switch disposed on the exterior of the case, wherein the power switch is coupled to the modem, such that a user may operate the power switch to initiate a first wireless communication channel between the modem and a cellular node and a second communication channel between the WIFI transceiver and a user device, external to the sealed compartment, without accessing an interior of the sealed compartment and without disrupting the seal, thereby enabling relay of data packets between an endpoint and the user device.

Clause 2. The communication case of Clause 1, wherein the panel hermetically seals the sealed compartment from the exterior of the case and from the first compartment.

Clause 3. The communication case of Clause 1, wherein the modem includes: (1) at least two SIMs including a first SIM and a second SIM, and (2) a plurality of antenna terminals for a plurality of antennas including at least two cellular antennas.

Clause 4. The communication case of Clause 3, further comprising an external ethernet port disposed on the exterior of the case that provides an ethernet connection on the interior wall of the case in the sealed compartment.

Clause 5. The communication case of Clause 4, wherein the modem further includes: a modem ethernet port connected to the ethernet connection.

Clause 6. The communication case of Clause 1, wherein the modem is configured to: (1) determine wireless communication channels for cellular networks and/or WIFI networks available at a location of the case, (2) determine signal characteristics of available cellular networks and/or WIFI networks, (3) select a wireless communication channel as the first wireless communication channel from among the available cellular networks and/or WIFI networks based on the signal characteristics, and (4) relay the data packets between the user device, when the user device is connected to an ethernet port or the WIFI transceiver, and the endpoint via the selected wireless communication channel.

Clause 7. The communication case of Clause 1, further comprising at least one indicator light disposed on the exterior wall of the case that provides at least one indicator connection on the interior wall of the case in the sealed compartment, and the modem further includes at least one indicator output connected to the at least one indicator connection.

Clause 8. The communication case of Clause 7, wherein the modem, after connecting with the endpoint, causes the at least one indicator light to indicate the communication case is ready for communication.

Clause 9. The communication case of Clause 7, wherein the at least one indicator light includes a first indicator light and a second indicator light, wherein the first indicator light indicates the modem is powered on, and wherein the second indicator light indicates the modem is connecting and/or connected to the endpoint.

Clause 10. The communication case of Clause 1, further comprising a first external ethernet port and a second external ethernet port disposed in the exterior wall of the case, and wherein the first external ethernet port and the second external ethernet port provide a first ethernet connection and a second ethernet connection on the interior wall of the case in the sealed compartment, and wherein the modem includes a first modem ethernet port connected to the first ethernet connection and a second modem ethernet port connected to the second ethernet connection.

Clause 11. The communication case of Clause 10, wherein the modem is configured to relay data packets between the second ethernet port and the endpoint, when a second user device is connected to the second ethernet port.

Clause 12. The communication case of Clause 10, wherein the modem is configured to relay the data packets between the first ethernet port and the second ethernet port, when the second ethernet port is connected to a local area network, a second communication case, a communication cart, or an external cellular modem.

Clause 13. The communication case of Clause 1, wherein the modem is configured to relay the data packets across multiple wireless communication channels.

Clause 14. The communication case of Clause 1, wherein the modem is configured to relay duplicates of the data packets across at least a second wireless communication channel.

Clause 15. The communication case of Clause 1, wherein the modem includes a plurality of antenna terminals for a plurality of antennas, wherein the plurality of antennas include sets of paired antennas, and wherein each of the paired antennas are orthogonally orientated with respect to another of the paired antennas within the sealed compartment.

Clause 16. The communication case of Clause 1, wherein the modem includes a plurality of antenna terminals for a plurality of antennas, wherein the plurality of antennas are terminal mounted antennas.

Clause 17. The communication case of Clause 16, wherein the terminal mounted antennas are monopole antennas.

Clause 18. The communication case of Clause 1, wherein the modem includes a plurality of antenna terminals for a plurality of antennas, and wherein the plurality of antennas include PCB antennas and/or flex antennas.

Clause 19. The communication case of Clause 18, wherein the PCB antennas and/or flex antennas are mounted on the panel in the sealed compartment, on sides of the modem, or on interior walls of the case in the sealed compartment.

Clause 20. The communication case of Clause 1, wherein the modem includes: at least two SIMs including a first SIM and a second SIM, wherein the first SIM and the second SIM are each one of: a network SIM, an electronic SIM, or a remote SIM injected across a network.

Clause 21. The communication case of Clause 1, wherein the modem includes: at least two SIMs including a first SIM and a second SIM, wherein the first SIM and the second SIM are each configured for a respective one of a first cellular network and a second cellular network, wherein the at least two SIMS includes a third SIM, and wherein the third SIM is a remote SIM.

Clause 22. The communication case of Clause 21, wherein the modem is configured to: (1) connect to a remote SIM injector via a selected wireless communication channel, (2) receive remote SIM data from the remote SIM injector, and (3) load the remote SIM with the virtual SIM data.

Clause 23. The communication case of Clause 22, wherein the virtual SIM data connects the modem to a cellular network different than the first cellular network and the second cellular network.

Clause 24. The communication case of Clause 1, wherein the modem is further configured to switch wireless communication channels when the signal characteristics change.

Clause 25. The communication case of Clause 1, wherein the modem is further configured to switch wireless communication channels when: (1) a change is detected while periodically redetermining signal characteristics, (2) a signal characteristic of the selected wireless communication channel falls below a threshold, or (3) detect the communication case has moved more than a threshold distance.

Clause 26. The communication case of Clause 1, wherein the modem is further configured to switch wireless communication channels when data use of the selected wireless communication channel crosses a threshold for a period of time.

Clause 27. The communication case of Clause 1, wherein the charging port and the charging connection are USB-C compatible.

Clause 28. The communication case of Clause 1, wherein the modem is configured to auto-boot when a power switch is operated by a user, the power switch being configured to provide power from the battery to the modem.

Clause 29. The communication case of Clause 1, wherein the battery is positioned on a bottom of the sealed compartment.

Clause 30. The communication case of Clause 1, wherein the battery and the modem are stacked on a bottom of the sealed compartment.

Clause 31. The communication case of Clause 30, wherein the modem is stacked on top of the battery.

Clause 32. The communication case of Clause 1, further comprising an external ethernet port disposed on the exterior of the case that provides an ethernet connection on the interior wall of the case in the sealed compartment, wherein the modem includes a modem ethernet port connected to the ethernet connection, wherein the external ethernet port is disposed on a first exterior wall of the case and the charging port is disposed on a second exterior wall of the case.

Clause 33. The communication case of Clause 32, further comprising at least one indicator light disposed on the exterior wall of the case that provides at least one indicator connection on the interior wall of the case in the sealed compartment, wherein the modem includes at least one indicator output connected to the at least one indicator connection, and wherein the charging port and the at least one indicator light is on same exterior wall of the case.

Clause 34. The communication case of Clause 33, wherein the modem further includes a plurality of antenna terminals for a plurality of antennas, wherein the plurality of antennas are positioned away from the external ethernet port, the charging port, and/or the at least one indicator light.

Clause 35. The communication case of Clause 1, wherein the first compartment is configured to hold a charging cable and/or a charger compatible with the charging port and the charging cable.

Clause 36. The communication case of Clause 1, wherein the first compartment is configured to hold disinfecting supplies.

Clause 37. The communication case of Clause 1, wherein the case includes a ledge to receive the panel, and the communication case further includes a seal between the panel and the ledge of the case to hermetically seal the sealed compartment.

Clause 38. The communication case of Clause 37, wherein the panel is affixed to the ledge via a plurality of fasteners.

Clause 39. The communication case of Clause 1, further comprising a handle and a latch, wherein the latch locks and unlocks the case to open the first compartment.

Clause 40. The communication case of Clause 1, wherein the battery is an always on battery if it has sufficient charge.

Clause 41. The communication case of Clause 1, wherein the battery is configured to, after being depleted and recharged, provide a set power delivery instead of a default value.

Clause 42. A communication cart, comprising: a communication compartment, wherein the communication compartment includes: a modem positioned within the communication compartment, and a WIFI transceiver positioned within the communication compartment, wherein the modem is configured to initiate a first wireless communication channel between the modem and a cellular node and a second communication channel between the WIFI transceiver and a user device, thereby enabling relay of data packets between an endpoint and the user device; a sanitization station, wherein the sanitization station includes a sanitization system configured to sanitize the user device; and a set of wheels for maneuvering the communication cart.

Clause 43. The modem is configured to initiate a first wireless communication without accessing an interior of the communication compartment.

Clause 44. The communication cart of Clause 42, wherein the communication compartment is similar in size to the sanitization station.

Clause 45. The communication cart of Clause 42, wherein the communication compartment has a same footprint as the sanitization station.

Clause 46. The communication cart of Clause 42, wherein the communication compartment and the sanitization station are stacked on the set of wheels.

Clause 47. The communication cart of Clause 42, wherein the communication compartment is stacked on top of the sanitization station.

Clause 48. The communication cart of Clause 42, wherein the sanitization station is stacked on top of the communication compartment.

Clause 49. The communication cart of Clause 42, wherein the communication compartment and the sanitization station are arranged laterally adjacent each other on the set of wheels.

Clause 50. The communication cart of Clause 42, wherein the communication compartment further includes an external ethernet port disposed on an exterior of the communication compartment that provides an ethernet connection on an interior wall of the communication compartment.

Clause 51. The communication cart of Clause 42, wherein the modem includes: (1) at least two SIMs including a first SIM and a second SIM, and (2) a plurality of antenna terminals for a plurality of antennas including at least two cellular antennas.

Clause 52. The communication cart of Clause 51, wherein the communication compartment further includes an external ethernet port disposed on an exterior of the communication compartment that provides an ethernet connection on an interior wall of the communication compartment, and wherein the modem further includes a modem ethernet port connected to the ethernet connection.

Clause 53. The communication cart of Clause 42, wherein the modem is configured to: (1) determine wireless communication channels for cellular networks and/or WIFI networks available at a location of the communication cart, (2) determine signal characteristics of available cellular networks and/or WIFI networks, (3) select a wireless communication channel as the first wireless communication channel from among the available cellular networks and/or WIFI networks based on the signal characteristics, and (4) relay the data packets between the user device, when the user device is connected to an ethernet port or the WIFI transceiver, and the endpoint via the selected wireless communication channel.

Clause 54. The communication cart of Clause 42, wherein the communication compartment further includes: at least one indicator light disposed on an exterior wall of the communication compartment that provides at least one indicator connection on an interior wall of the communication compartment, and the modem includes at least one indicator output connected to the at least one indicator connection.

Clause 55. The communication cart of Clause 54, wherein the modem is configured to, after connecting with the endpoint, cause the at least one indicator light to indicate the communication cart is ready for communication.

Clause 56. The communication cart of Clause 54, wherein the at least one indicator light includes a first indicator light and a second indicator light, wherein the first indicator light indicates the modem is powered on, and wherein the second indicator light indicates the modem is connecting and/or connected to the endpoint.

Clause 57. The communication cart of Clause 42, wherein the communication compartment further includes: a first external ethernet port and a second external ethernet port disposed on an exterior wall of the communication compartment that provide, respectively, a first ethernet connection and a second ethernet connection on an interior wall of the communication compartment, and the modem includes a first modem ethernet port and a second modem ethernet port connected, respectively, to the first ethernet connection and the second ethernet connection.

Clause 58. The communication cart of Clause 57, wherein the modem is configured to relay data packets between the second ethernet port and the endpoint, when a second user device is connected to the second ethernet port.

Clause 59. The communication cart of Clause 57, wherein the modem is configured to relay the data packets between the first ethernet port and the second ethernet port, when the second ethernet port is connected to a local area network, a second communication cart, a communication case, or an external cellular modem.

Clause 60. The communication cart of Clause 42, wherein the modem is configured to relay the data packets across multiple wireless communication channels.

Clause 61. The communication cart of Clause 42, wherein the modem is configured to relay duplicates of the data packets across at least a second wireless communication channel.

Clause 62. The communication cart of Clause 42, wherein the modem includes a plurality of antenna terminals for a plurality of antennas,

Clause 63. The communication cart of Clause 62, wherein the plurality of antennas include sets of paired antennas, and wherein each of the paired antennas are orthogonally orientated with respect to another of the paired antennas.

Clause 64. The communication cart of Clause 62, wherein the plurality of antennas include dome antennas disposed on an exterior of the communication compartment.

Clause 65. The communication cart of Clause 64, wherein the dome antennas are evenly distributed on an exterior of the communication compartment.

Clause 66. The communication cart of Clause 64, wherein the dome antennas are disposed on different exterior walls or top of the communication compartment.

Clause 67. The communication cart of Clause 64, wherein the dome antennas are disposed on orthogonal walls or top of the communication compartment, or opposite exterior walls.

Clause 68. The communication cart of Clause 62, wherein the plurality of antennas include terminal mounted antennas.

Clause 69. The communication cart of Clause 68, wherein the terminal mounted antennas are monopole antennas.

Clause 70. The communication cart of Clause 62, wherein the plurality of antennas include PCB antennas and/or flex antennas.

Clause 71. The communication cart of Clause 70, wherein the PCB antennas and/or the flex antennas are mounted on interior walls of the communication compartment, on sides of the modem, or on other components of the communication compartment.

Clause 72. The communication cart of Clause 62, wherein the plurality of antennas include integrated antennas.

Clause 73. The communication cart of Clause 72, wherein the integrated antennas are formed in a housing of the modem using laser direct structuring and/or molded interconnect device processes.

Clause 74. The communication cart of Clause 42, wherein the modem includes at least two SIMs including a first SIM and a second SIM.

Clause 75. The communication cart of Clause 74, wherein the first SIM and the second SIM are each one of: a network SIM, an electronic SIM, or a remote SIM injected across a network.

Clause 76. The communication cart of Clause 74, wherein the first SIM and the second SIM are each configured for a respective one of a first cellular network and a second cellular network, and wherein the at least two SIMS includes a third SIM, and wherein the third SIM is a remote SIM

Clause 77. The communication cart of Clause 76, wherein the modem is configured to: (1) connected to a remote SIM injector via the selected wireless communication channel, (2) receive remote SIM data from the remote SIM injector, and (3) load the remote SIM with the virtual SIM data.

Clause 78. The communication cart of Clause 77, wherein the virtual SIM data connects the modem to a cellular network different than the first cellular network and the second cellular network.

Clause 79. The communication cart of Clause 42, wherein the modem is configured to switch wireless communication channels when signal characteristics change.

Clause 80. The communication cart of Clause 42, wherein the modem is further configured to switch wireless communication channels when: (1) a change is detected while periodically redetermining signal characteristics, (2) a signal characteristic of the selected wireless communication channel falls below a threshold, or (3) detect the communication cart has moved more than a threshold distance.

Clause 81. The communication cart of Clause 42, wherein the modem is further configured to switch wireless communication channels when data use of the selected wireless communication channel crosses a threshold for a period of time.

Clause 82. The communication cart of Clause 42, wherein the communication cart further includes a communication switch, and wherein the communication switch is coupled to the modem, such that a user may operate the communication switch to initiate at least the first wireless communication channel.

Clause 83. The communication cart of Clause 82, wherein the communication switch is disposed on an exterior of the communication compartment.

Clause 84. The communication cart of Clause 42, wherein the communication cart further includes: a charging port disposed on an exterior of the communication compartment that provides a charging connection on an interior wall of the communication compartment; and a battery positioned within the communication compartment and configured to be charged by the charging connection when an external charging device is connected to the charging port.

Clause 85. The communication cart of Clause 84, wherein the battery powers one or more of the modem, the WIFI transceiver, and/or the sanitization system.

Clause 86. The communication cart of Clause 83, wherein the charging port and the charging connection are USB-C compatible, AC outlet compatible, or DC outlet compatible.

Clause 87. The communication cart of Clause 84, wherein the modem is further configured to auto-boot when a power switch is operated by a user, wherein the power switch is configured to provide power from the battery to the modem.

Clause 88. The communication cart of Clause 84, wherein the battery is positioned on a bottom of the communication compartment.

Clause 89. The communication cart of Clause 84, wherein the battery and the modem are stacked on a bottom of the communication compartment.

Clause 90. The communication cart of Clause 84, wherein the battery and the modem are positioned adjacent to each other.

Clause 91. The communication cart of Clause 84, wherein the communication compartment is configured to hold a charging cable and/or charger compatible with the charging port and the charging cable.

Clause 92. The communication cart of Clause 84, wherein the battery is an always on battery if it has sufficient charge.

Clause 93. The communication cart of Clause 84, wherein the battery is configured to, after being depleted and recharged, provide a set power delivery instead of a default value.

Clause 94. The communication cart of Clause 84, wherein the battery provides DC and AC power supply.

Clause 95. The communication cart of Clause 42, wherein the sanitization station is a sanitization compartment, and the sanitization station includes a sanitization switch disposed on an exterior of the sanitization compartment, wherein the sanitization switch is coupled to the sanitization system, so that when the user operates the sanitization switch the sanitization system starts a sanitization process of the sanitization system.

Clause 96. The communication cart of Clause 42, wherein the sanitization station includes a platform positioned in a zone of the sanitization station and configured to hold the user device.

Clause 97. The communication cart of Clause 96, wherein the platform is transparent to germicidal wavelengths of electromagnetic radiation.

Clause 98. The communication cart of Clause 96, wherein the platform is transparent to ultraviolet radiation having 222 or 254 nanometer wavelength light.

Clause 99. The communication cart of Clause 96, wherein the platform has a surface configured to hold the user device and supports configured to position the surface above a bottom of the sanitization station in the zone.

Clause 100. The communication cart of Clause 42, wherein the sanitization station is a sanitization compartment, and the sanitization system includes a plurality of ultraviolet radiation lamps and a platform positioned in a zone of the sanitization station and configured to hold the user device.

Clause 101. The communication cart of Clause 100, wherein the plurality of ultraviolet radiation lamps are disposed on interior walls of the sanitization compartment.

Clause 102. The communication cart of Clause 100, wherein the plurality of ultraviolet radiation lamps radiate the platform from at least two sides of the platform.

Clause 103. The communication cart of Clause 102, wherein the at least two sides of the platform are opposite each other.

Clause 104. The communication cart of Clause 100, wherein the plurality of ultraviolet radiation lamps radiate the platform from four orthogonal sides of the platform.

Clause 105. The communication cart of Clause 100, wherein the plurality of ultraviolet radiation lamps radiate the platform from above and below the platform.

Clause 106. The communication cart of Clause 100, wherein the sanitization compartment includes reflective material on interior walls of the sanitization compartment.

Clause 107. The communication cart of Clause 100, wherein the sanitization compartment has a door configured to be opened and closed.

Clause 108. The communication cart of Clause 100, wherein the sanitization compartment is sealed when closed.

Clause 109. The communication cart of Clause 42, wherein the sanitization system is powered by a battery in the communication compartment.

Clause 110. The communication cart of Clause 42, wherein the sanitization system is a far ultraviolet system.

Clause 111. The communication cart of Clause 110, wherein the far ultraviolet system is configured to be always on.

Clause 112. The communication cart of Clause 110, wherein the far ultraviolet system of the sanitization station is positioned on top or an exterior side of the communication compartment, or above the communication compartment.

Clause 113. The communication cart of Clause 112, wherein the far ultraviolet system radiates ultraviolet radiation to a zone, wherein the zone is designated for the user to hold or pass the user device through the zone so as to radiate the user device with the ultraviolet radiation.

Clause 114. The communication cart of Clause 42, wherein the communication compartment further includes an edge compute node.

Clause 115. The communication cart of Clause 114, wherein the edge compute node is hosted on the modem.

Clause 116. The communication cart of Clause 114, wherein the edge compute node is an edge computer positioned within the communication compartment and connected to the modem.

Clause 117. The communication cart of Clause 114, wherein the edge compute node serves AI applications, extended reality applications, learning applications, video conferencing applications, and/or on-edge processing applications to the user device.

Clause 118. The communication cart of Clause 114, wherein the communication compartment further includes at least one camera disposed on an exterior of the communication compartment and connected to the edge compute node.

Clause 119. The communication cart of Clause 118, wherein the least one camera includes a three-dimensional camera.

Clause 120. The communication cart of Clause 114, wherein the communication compartment further includes at least one audio/visual component disposed on an exterior of the communication compartment and connected to the edge compute node.

Clause 121. The communication cart of Clause 120, wherein the at least one audio/visual component includes one or more combinations of a HDMI port, a display port, a USB port, a speaker, a projector, a display, and/or a motion sensor.

Clause 122. The communication cart of Clause 114, wherein the set of wheels include motorized wheels.

Clause 123. The communication cart of Clause 122, wherein the edge compute node is configured to control the motorized wheels.

Clause 124. The communication cart of Clause 123, wherein the edge compute node is configured to control the motorized wheels based on user inputs and/or sensor data indicating a sensed environment, and wherein the sensor data is sensed by at least one sensor.

Clause 125. The communication cart of Clause 124, wherein the at least one sensor includes one or combinations of: camera(s), proximity sensor(s), motion sensor(s), an ultrasound system, a radar system, and/or a lidar system.

Other aspects of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A communication case adopted for exposure to biological material, the communication case comprising:
a case, wherein the case includes two compartments within an interior volume of the case, wherein the case is configured to be opened to provide access to a first compartment of the two compartments;
a panel, wherein the panel is positioned to separate a sealed compartment of the two compartments within the case from the first compartment, and wherein the panel seals the sealed compartment from an exterior of the case and from the first compartment;
a modem positioned within the sealed compartment;
a WIFI transceiver positioned within the sealed compartment; and
a power switch disposed on the exterior of the case, wherein the power switch is coupled to the modem, such that a user may operate the power switch to initiate a first wireless communication channel between the modem and a cellular node and a second communication channel between the WIFI transceiver and a user device, external to the sealed compartment, without accessing an interior of the sealed compartment and without disrupting the seal, thereby enabling relay of data packets between an endpoint and the user device.

2. The communication case of claim 1, wherein the panel hermetically seals the sealed compartment from the exterior of the case and from the first compartment.

3. The communication case of claim 1, wherein the modem includes: (1) at least two SIMs including a first SIM and a second SIM, and (2) a plurality of antenna terminals for a plurality of antennas including at least two cellular antennas.

4. The communication case of claim 1, wherein the modem is configured to: (1) determine wireless communication channels for cellular networks and/or WIFI networks available at a location of the case, (2) determine signal characteristics of available cellular networks and/or WIFI networks, (3) select a wireless communication channel as the first wireless communication channel from among the available cellular networks and/or WIFI networks based on the signal characteristics, and (4) relay the data packets between the user device, when the user device is connected to an ethernet port or the WIFI transceiver, and the endpoint via the selected wireless communication channel.

5. The communication case of claim 1, wherein the modem is configured to relay the data packets across multiple wireless communication channels.

6. The communication case of claim 1, wherein the modem is configured to relay duplicates of the data packets across at least a second wireless communication channel.

7. The communication case of claim 1, wherein the modem includes a plurality of antenna terminals for a plurality of antennas, wherein the plurality of antennas include sets of paired antennas, and wherein each of the paired antennas are orthogonally orientated with respect to another of the paired antennas within the sealed compartment.

8. The communication case of claim 1, wherein the modem includes a plurality of antenna terminals for a plurality of antennas, wherein the plurality of antennas are terminal mounted antennas.

9. The communication case of claim 1, wherein the modem includes a plurality of antenna terminals for a plurality of antennas, and wherein the plurality of antennas include (a) a phased antenna array and/or (b) PCB antennas and/or flex antennas.

10. The communication case of claim 1, wherein the modem includes: at least two SIMs including a first SIM and a second SIM, wherein the first SIM and the second SIM are each one of: a network SIM, an electronic SIM, or a remote SIM injected across a network.

11. The communication case of claim 1, wherein the modem includes: at least two SIMs including a first SIM and a second SIM, wherein the first SIM and the second SIM are each configured for a respective one of a first cellular network and a second cellular network, wherein the at least two SIMS includes a third SIM, and wherein the third SIM is a remote SIM.

12. The communication case of claim 1, wherein the modem is further configured to switch wireless communication channels when signal characteristics change.

13. The communication case of claim 1, wherein the modem is further configured to switch wireless communication channels when: (1) a change is detected while periodically redetermining signal characteristics, (2) a signal characteristic of a selected wireless communication channel falls below a threshold, or (3) detect the communication case has moved more than a threshold distance.

14. The communication case of claim 1, wherein the modem is further configured to switch wireless communication channels when data use of the selected wireless communication channel crosses a threshold for a period of time.

15. The communication case of claim 1, further comprising: a charging port disposed on the exterior of the case that provides a charging connection on an interior wall of the case in the sealed compartment; and a battery positioned within the sealed compartment and configured to be charged by the charging connection when an external charging device is connected to the charging port, wherein the modem is configured to auto-boot when a power switch is operated by a user, the power switch being configured to provide power from the battery to the modem.

16. The communication case of claim 1, further comprising: a charging port disposed on the exterior of the case that provides a charging connection on an interior wall of the case in the sealed compartment; and a battery positioned within the sealed compartment and configured to be charged by the charging connection when an external charging device is connected to the charging port, wherein the battery is positioned on a bottom of the sealed compartment.

17. The communication case of claim 1, further comprising: a charging port disposed on the exterior of the case that provides a charging connection on an interior wall of the case in the sealed compartment; and a battery positioned within the sealed compartment and configured to be charged by the charging connection when an external charging device is connected to the charging port, wherein the battery and the modem are stacked on a bottom of the sealed compartment.

18. The communication case of claim 1, wherein the case includes a ledge to receive the panel, and the communication case further includes a seal between the panel and the ledge of the case to hermetically seal the sealed compartment.

19. The communication case of claim 1, further comprising: a charging port disposed on the exterior of the case that provides a charging connection on an interior wall of the case in the sealed compartment; and a battery positioned within the sealed compartment and configured to be charged by the charging connection when an external charging device is connected to the charging port, wherein the battery is an always on battery if it has sufficient charge.

20. The communication case of claim 1, further comprising: a charging port disposed on the exterior of the case that provides a charging connection on an interior wall of the case in the sealed compartment; and a battery positioned within the sealed compartment and configured to be charged by the charging connection when an external charging device is connected to the charging port, wherein the battery is configured to, after being depleted and recharged, provide a set power delivery instead of a default value.
